(19) United States
(12) Patent Application Publication
(10) Pub. No.: US 2025/0393447 A1
(43) Pub. Date: Dec. 25, 2025

(54) DISPLAY DEVICE AND ELECTRONIC DEVICE

(71) Applicant: Samsung Display Co., LTD., Yongin-si (KR)

(72) Inventor: Cheon Myeong LEE, Yongin-si (KR)

(73) Assignee: Samsung Display Co., LTD., Yongin-si (KR)

(21) Appl. No.: 19/204,784

(22) Filed: May 12, 2025

(30) Foreign Application Priority Data
Jun. 20, 2024 (KR) 10-2024-0080525
Aug. 20, 2024 (KR) 10-2024-0110976

(51) Int. Cl. H10K 59/80; H10K 59/122

(52) U.S. Cl. CPC H10K 59/878; H10K 59/122

(57) ABSTRACT

Provided is a display device including: a first electrode; a pixel defining layer on the first electrode; a light emitting member on the first electrode and the pixel defining layer; a second electrode on the light emitting member; an organic layer on the second electrode; a first reflective layer in the organic layer; and a second reflective layer disposed on the first reflective layer in the organic layer, wherein the first reflective layer overlaps the pixel defining layer, and the second reflective layer overlaps the light emitting member in a thickness direction.

### CROSS-REFERENCE TO RELATED APPLICATION(S)

This application claims priority to and the benefit of Korean Patent Application No. 10-2024-0080525 under 35 U.S.C. § 119, filed on Jun. 20, 2024, and 10-2024-0110976 under 35 U.S.C. § 119, filed on Aug. 20, 2024, in the Korean Intellectual Property Office, the entire contents of which are incorporated herein by references.

### BACKGROUND

### 1. Technical Field

The disclosure generally relates to a display device and an electronic device. More particularly, the disclosure relates to a display device capable of improving light emission efficiency.

### 2. Description of the Related Art

Research and development for display devices has been ongoing recently due to the growing interest in display devices.

### SUMMARY

An object of the disclosure is to improve light emission efficiency of a display device.

Embodiments of the disclosure are not limited to the embodiment mentioned above, and other technical objects that are not mentioned may be clearly understood to a person of an ordinary skill in the art using the following description.

An embodiment provides a display device including: a first electrode; a pixel defining layer disposed on the first electrode; a light emitting member disposed on the first electrode and the pixel defining layer; a second electrode disposed on the light emitting member; an organic layer disposed on the second electrode; a first reflective layer in the organic layer; and a second reflective layer disposed on the first reflective layer in the organic layer, wherein the first reflective layer overlaps the pixel defining layer, and the second reflective layer overlaps the light emitting member in a thickness direction.

A planar area of the first reflective layer may be larger than a planar area of the second reflective layer.

The pixel defining layer may include an opening overlapping the first electrode in the thickness direction, and the second reflective layer may overlap the opening in the thickness direction.

The first reflective layer may include a first opening.

The second reflective layer may include a second opening.

A planar area of the first opening may be larger than a planar area of the second opening.

The first reflective layer and the second reflective layer may include an inclined surface.

The first reflective layer and the second reflective layer may include a spherical surface.

The pixel defining layer may include a separator, and the light emitting member may be at least partially separated by the separator.

Another embodiment provides a display device including: a first electrode; a pixel defining layer disposed on the first electrode; a light emitting member disposed on the first electrode and the pixel defining layer; a second electrode disposed on the light emitting member; a first organic layer disposed on the second electrode; a first reflective layer on the first organic layer; a second organic layer disposed on the first reflective layer; and a second reflective layer disposed on the second organic layer, wherein the first reflective layer overlaps the pixel defining layer, and the second reflective layer overlaps the light emitting member in a thickness direction.

The first organic layer may include a first inclined surface, and the first reflective layer may be disposed on the first inclined surface.

The second organic layer may include a second inclined surface, and the second reflective layer may be disposed on the second inclined surface.

The first reflective layer may include a first opening.

The first organic layer may be disposed in the first opening.

The second reflective layer may include a second opening.

The second organic layer may be disposed in the second opening.

A planar area of the first reflective layer may be larger than a planar area of the second reflective layer.

The display device may further include a third organic layer on the second reflective layer.

The first organic layer, the second organic layer, and/or the third organic layer may include the same material.

According to an embodiment of the disclosure, an electronic device may include a display device including a light emitting element disposed on a substrate, wherein the light emitting element includes: a display device including a light emitting element disposed on a substrate, wherein the light emitting element includes: a first electrode; a pixel defining layer disposed on the first electrode; a light emitting member disposed on the first electrode and the pixel defining layer; a second electrode disposed on the light emitting member; an organic layer disposed on the second electrode; a first reflective layer in the organic layer; and a second reflective layer disposed on the first reflective layer in the organic layer. The first reflective layer may overlap the pixel defining layer, and the second reflective layer may overlap the light emitting member in a thickness direction.

Particularities of other embodiments are included in the detailed description and drawings.

According to the above-described embodiment, a manufacturing process may be simplified and light emission efficiency may be improved by forming an optical layer using an organic layer and reflective layers.

Effects of the embodiments of the disclosure are not limited by what is illustrated in the above, and more various effects are included in the present specification.

### BRIEF DESCRIPTION OF THE DRAWINGS

FIG. 1 illustrates a schematic block diagram of a display device according to an embodiment.

FIG. 2 illustrates a schematic block diagram of one of sub-pixels of FIG. 1 according to an embodiment.

FIG. 3 illustrates a schematic diagram of an equivalent circuit of the sub-pixel of FIG. 2 according to an embodiment.

FIG. 4 illustrates a schematic top plan view of a display panel of FIG. 1 according to an embodiment.

FIG. 5 illustrates an exploded schematic perspective view of a portion of a display panel of FIG. 4.

FIG. 6 illustrates a schematic top plan view of one of pixels of FIG. 5 according to an embodiment.

FIG. 7 to FIG. 11 illustrate schematic cross-sectional views taken along line I-I′ of FIG. 6.

FIG. 12 illustrates an enlarged schematic view of reflective layers of FIG. 7 according to an embodiment.

FIG. 13 illustrates a schematic cross-sectional view taken along line I-I′ of FIG. 6 according to another embodiment.

FIG. 14 illustrates an enlarged schematic view of area “A” of FIG. 13.

FIG. 15 illustrates a schematic cross-sectional view of a portion of a light emitting structure included in one of first to third light emitting elements of FIG. 7 to FIG. 11 or FIG. 13 according to an embodiment.

FIG. 16 illustrates a schematic cross-sectional view of a portion of a light emitting structure included in one of first to third light emitting elements of FIG. 7 to FIG. 11 or FIG. 13 according to another embodiment.

FIG. 17 illustrates a schematic top plan view of one of pixels of FIG. 5 according to another embodiment.

FIG. 18 illustrates a schematic top plan view of one of pixels of FIG. 5 according to another embodiment.

FIG. 19 illustrates a schematic block diagram of a display system according to an embodiment.

FIG. 20 illustrates a schematic perspective view of an application example of the display system of FIG. 19.

FIG. 21 illustrates a schematic head-mounted display device of FIG. 20 worn by a user.

FIG. 22 to FIG. 28 illustrate schematic cross-sectional views of process steps of a manufacturing method of a display device according to an embodiment.

### DETAILED DESCRIPTION OF THE EMBODIMENTS

Hereinafter, example embodiments of the disclosure will be described in detail with reference to the accompanying drawings. The following description is intended to provide only a sufficient disclosure to enable the understanding of the operation of the disclosure, and any other disclosure is omitted to avoid obscuring the scope of the disclosure. The inventive concept may be embodied in different forms and is not limited to the embodiments set forth herein. The embodiments described herein are provided for the purpose of describing the technical concept of the disclosure in sufficient detail for those skilled in the art to readily practice it.

Throughout the specification, in case that it is described that an element is “connected” to another element, this includes not only being “directly connected”, but also being “indirectly connected” with another device in between. The terms used herein are for the purpose of describing specific embodiments and are not intended to limit the scope of the invention. Throughout the specification, unless explicitly described to the contrary, the word “comprise” and variations such as “comprises” or “comprising” will be understood to imply the inclusion of stated elements but not the exclusion of any other elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various constituent elements, these constituent elements should not be limited by these terms. These terms are used to distinguish one constituent element from another. Thus, a first constituent element discussed below could be termed a second constituent element without departing from the teachings of the disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments are described herein with reference to sectional illustrations that are schematic illustrations of idealized embodiments. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

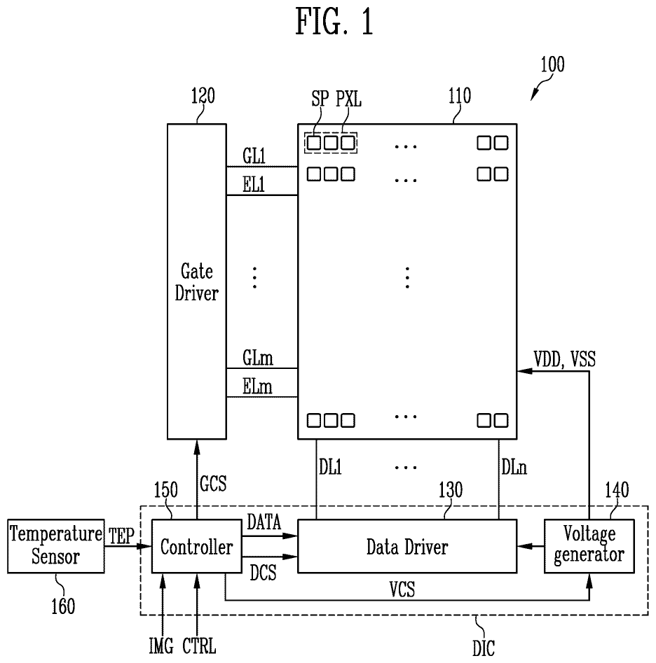

FIG. 1 illustrates a schematic block diagram of a display device according to an embodiment.

Referring to FIG. 1, a display device 100 may include a display panel 110, a gate driver 120, a data driver 130, a voltage generator 140, and a controller 150.

The display panel 110 may include sub-pixels SP. The sub-pixels SP may be electrically connected to the gate driver 120 through first to m-th gate lines GL1 to GLm. The sub-pixels SP may be electrically connected to the data driver 130 through first to n-th data lines DL1 to DLn.

Each of the sub-pixels SP may include at least one light emitting element that generates light. Accordingly, the sub-pixels SP may respectively generate light of a specific color such as red, green, blue, cyan, magenta, yellow, or the like. Two or more of the sub-pixels SP may configure one pixel PXL. For example, as shown in FIG. 1, three sub-pixels may configure one pixel PXL.

The gate driver 120 may be electrically connected to the sub-pixels SP arranged in a row direction through the first to m-th gate lines GL1 to GLm. The gate driver 120 may output gate signals to the first to m-th gate lines GL1 to GLm in response to a gate control signal GCS. The gate control signal GCS may include a start signal indicating the start of each frame, a horizontal synchronization signal for outputting gate signals in synchronization with the timing at which data signals are applied, and the like.

First to m-th light emitting control lines EL1 to ELm electrically connected to the sub-pixels SP in a row direction may be further provided. The gate driver 120 may include a light emitting control driver that controls the first to m-th light emitting control lines EL1 to ELm, and the light emitting control driver may operate under the control of the controller 150.

The gate driver 120 may be disposed on one side of the display panel 110. However, embodiments are not limited thereto. For example, the gate driver 120 may be divided into two or more physically and/or logically separated drivers, and the drivers may be disposed on one side of the display panel 110 and the other side of the display panel 110 opposite to the one side. As described above, the gate driver 120 may be disposed around the display panel 110 in various forms according to the embodiments.

The data driver 130 may be electrically connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. The data control signal DCS may include a source start pulse, a source shift clock, a source output enable signal, and the like.

The data driver 130 may use voltages from the voltage generator 140 to apply data signals having grayscale voltages corresponding to the image data DATA to the first to n-th data lines DL1 to DLn. In case that a gate signal is applied to each of the first to m-th gate lines GL1 to GLm, data signals corresponding to the image data DATA may be applied to the data lines DL1 to DLm. Accordingly, the corresponding sub-pixels SP may generate light corresponding to the data signals. Accordingly, an image may be displayed on the display panel 110.

The gate driver 120 and the data driver 130 may include complementary metal-oxide semiconductor (CMOS) circuit elements.

The voltage generator 140 may operate in response to a voltage control signal VCS from the controller 150. The voltage generator 140 may generate multiple voltages and provide the generated voltages to constituent elements of the display device 100. For example, the voltage generator 140 may generate multiple voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the first power voltage VDD. In other embodiments, the first power voltage VDD or the second power voltage VSS may be provided by an external device of the display device 100.

The voltage generator 140 may generate various voltages. For example, the voltage generator 140 may generate an initialization voltage applied to the sub-pixels SP. For example, during a sensing operation to sense electrical characteristics of transistors and/or light emitting elements of the sub-pixels SP, a predetermined reference voltage may be applied to the first to n-th data lines DL1 to DLn, and the voltage generator 140 may generate the reference voltage.

The controller 150 controls various operations of the display device 100. The controller 150 receives input image input IMG and a control signal CTRL for controlling the display of the input image data, from the outside. The controller 150 may provide the gate control signal GCS, the data control signal DCS, and the voltage control signal VCS in response to the control signal CTRL.

The controller 150 may convert the input image input IMG to be suitable for the display device 100 or the display panel 110 to output the image data DATA. The controller 150 may output the image data DATA by aligning the input image input IMG to be suitable for the sub-pixels SP of a row unit.

Two or more components of the data driver 130, the voltage generator 140 and the controller 150 may be mounted on one integrated circuit. As shown in FIG. 1, the data driver 130, the voltage generator 140 and the controller 150 may be included in a driver integrated circuit DIC. The data driver 130, the voltage generator 140 and the controller 150 may be functionally separate components in one driver integrated circuit DIC. In other embodiments, at least one of the data driver 130, the voltage generator 140 and the controller 150 may be provided as a component separated from the driver integrated circuit DIC.

The display device 100 may include at least one temperature sensor 160. The temperature sensor 160 may sense a surrounding temperature of the display device 100 and generate temperature data TEP representing the sensed temperature. The temperature sensor 160 may be disposed adjacent to the display panel 110 and/or the driver integrated circuit DIC.

The controller 150 may control various operations of the display device 100 in response to the temperature data TEP. The controller 150 may adjust the luminance of an image output from the display panel 110 in response to the temperature data TEP. For example, the controller 150 may control the data signals and the first and second power voltages VDD and VSS by controlling components such as the data driver 130 and/or the voltage generator 140.

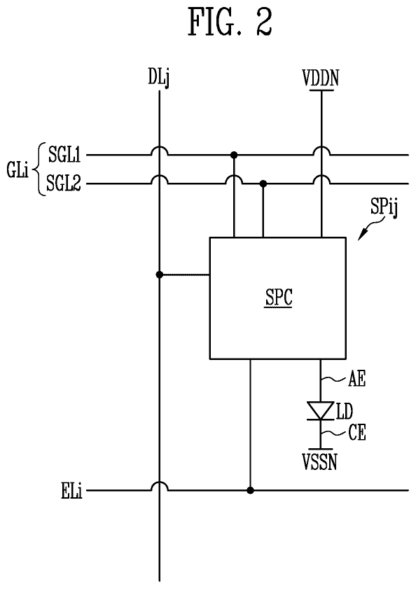

FIG. 2 illustrates a schematic block diagram of one of sub-pixels of FIG. 1 according to an embodiment. As depicted in FIG. 2, among the sub-pixels SP of FIG. 1, a sub-pixel SPij disposed in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light emitting element LD.

The light emitting element LD may be electrically connected between a first power voltage node VDDN and a second power voltage node VSSN. For example, the first power voltage node VDDN may be a node that transmits the first power voltage VDD of FIG. 1, and the second power voltage node VSSN may be a node that transmits the second power voltage VSS of FIG. 1.

An anode electrode AE of the light emitting element LD may be electrically connected to the first power voltage node VDDN through the sub-pixel circuit SPC, and a cathode electrode CE of the light emitting element LD may be electrically connected to the second power voltage node VSSN. For example, the anode electrode AE of the light emitting element LD may be electrically connected to the first power voltage node VDDN through one or more transistors included in the sub-pixel circuit SPC.

The sub-pixel circuit SPC may be electrically connected to an i-th gate line GLi among the first to m-th gate lines GL1 to GLm of FIG. 1, an i-th light emitting control line ELi among the first to m-th light emitting control lines EL1 to ELm of FIG. 1, and a j-th data line DLj among the first to n-th data lines DL1 to DLn of FIG. 1. The sub-pixel circuit SPC may control the light emitting element LD according to signals received through these signal lines.

The sub-pixel circuit SPC may operate in response to a gate signal received through the i-th gate line GLi. The i-th gate line GLi may include one or more sub-gate lines. As shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, in case that the i-th gate line GLi includes two or more sub-gate lines, the sub-pixel circuit SPC may operate in response to gate signals received through the corresponding sub-gate lines.

The sub-pixel circuit SPC may operate in response to a light emitting control signal received through the i-th light emitting control line ELi. The i-th light emitting control line ELi may include one or more sub-light emitting control lines. In case that the i-th light emitting control line ELi includes two or more sub-light emitting control lines, the sub-pixel circuit SPC may operate in response to light emitting control signals received through the corresponding sub-light emitting control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. In response to the light emitting control signal received through the i-th light emitting control line ELi, the sub-pixel circuit SPC may adjust the current flowing from the first power voltage node VDDN to the second power voltage node VSSN through the light emitting element LD according to the stored voltage. Accordingly, the light emitting element LD may generate light of luminance corresponding to the data signal.

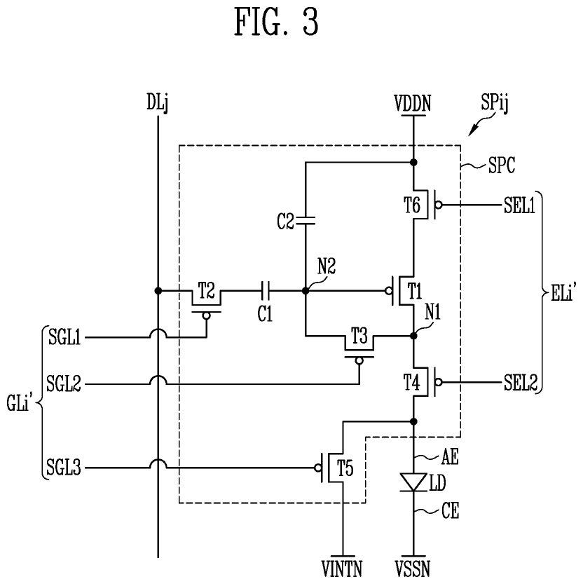

FIG. 3 illustrates a schematic diagram of an equivalent circuit of the sub-pixel of FIG. 2 according to an embodiment.

Referring to FIG. 3, the sub-pixel SPij may include a sub-pixel circuit SPC and a light emitting element LD.

The sub-pixel circuit SPC may be electrically connected to an i-th gate line GLi′, an i-th light emitting control line ELi′ and a j-th data line DLj. Compared to the i-th gate line GLi of FIG. 2, the i-th gate line GLi′ may further include a third sub-gate line SGL3. Compared to the i-th light emitting control line ELi of FIG. 2, the i-th light emitting control line ELi′ may include a first sub-light emitting control line SEL1 and a second sub-light emitting control line SEL2.

The sub-pixel circuit SPC may include the first to sixth transistors T1 to T6 and the first and second capacitors C1 and C2.

The first transistor T1 may be electrically connected between the first power voltage node VDDN and a first node N1. A gate of the first transistor T1 may be electrically connected to a second node N2, and accordingly, the first transistor T1 may be turned on according to a voltage level of the second node N2. The first transistor T1 may be referred to as a driving transistor.

The second transistor T2 may be electrically connected between the j-th data line DLj and the second node N2. A gate of the second transistor T2 may be electrically connected to the first sub-gate line SGL1, and accordingly, the second transistor T2 may be turned on in response to the gate signal of the first sub-gate line SGL1. The second transistor T2 may be referred to as a switching transistor.

The third transistor T3 may be electrically connected between the first node N1 and the second node N2. A gate of the third transistor T3 may be electrically connected to the second sub-gate line SGL2, and accordingly, the third transistor T3 may be turned on in response to the gate signal of the second sub-gate line SGL2.

The fourth transistor T4 may be electrically connected between the first node N1 and the anode electrode AE of the light emitting element LD. A gate of the fourth transistor T4 may be electrically connected to the second sub-light emitting control line SEL2, and accordingly, the fourth transistor T4 may be turned on in response to the light emitting control signal of the second sub-light emitting control line SEL2.

The fifth transistor T5 may be electrically connected between the anode electrode AE of the light emitting element LD and an initialization voltage node VINTN. The initialization voltage node VINTN may transmit an initialization voltage. The initialization voltage may be provided by the voltage generator 140 of FIG. 1. In other embodiments, the initialization voltage may be provided by an external device to the display device 100. A gate of the fifth transistor T5 may be electrically connected to the third sub-gate line SGL3, and accordingly, the fifth transistor T5 may be turned on in response to the gate signal of the third sub-gate line SGL3.

The sixth transistor T6 may be electrically connected between a first power voltage node VDDN and the first transistor T1. A gate of the sixth transistor T6 may be electrically connected to the first sub-light emitting control line SEL1, and accordingly, the sixth transistor T6 may be turned on in response to the light emitting control signal of the first sub-light emitting control line SEL1.

The first capacitor C1 may be electrically connected between the second transistor T2 and the second node N2. The second capacitor C2 may be electrically connected between the first power voltage node VDDN and the second node N2.

As described above, the sub-pixel circuit SPC may include the first to sixth transistors T1 to T6 and the first and second capacitors C1 and C2. However, embodiments are not limited thereto. The sub-pixel circuit SPC may be implemented as one of various circuits including multiple transistors and one or more capacitors. For example, the sub-pixel circuit SPC may include two transistors and one capacitor. According to the embodiments of the sub-pixel circuit SPC, the number of sub-gate lines included in the i-th gate line GLi′ and the number of sub-light emitting control lines included in the i-th light emitting control line ELi′ may vary.

The first to sixth transistors T1 to T6 may be P-type transistors. Each of the first to sixth transistors T1 to T6 may be a metal oxide silicon field effect transistor (MOSFET). However, embodiments are not limited thereto. For example, at least one of the first to sixth transistors T1 to T6 may be replaced with an N-type transistor.

The first to sixth transistors T1 to T6 may include an amorphous silicon semiconductor, a monocrystalline silicon semiconductor, a polycrystalline silicon semiconductor, and an oxide semiconductor.

The light emitting element LD may include the anode electrode AE, the cathode electrode CE, and the light emitting layer. The light emitting layer may be disposed between the anode electrode AE and the cathode electrode CE. After the data signal transmitted through the j-th data line DLj is reflected in the voltage of the second node N2, the fourth and sixth transistors T4 and T6 may be turned on in case that the light emitting control signals of the first and second sub-light emitting control lines SEL1 and SEL2 are enabled to a low level. The first transistor T1 may be turned on according to the voltage of the second node N2, and accordingly, a current may flow from the first power voltage node VDDN to the second power voltage node VSSN. The light emitting element LD may emit light depending on the amount of current flowing.

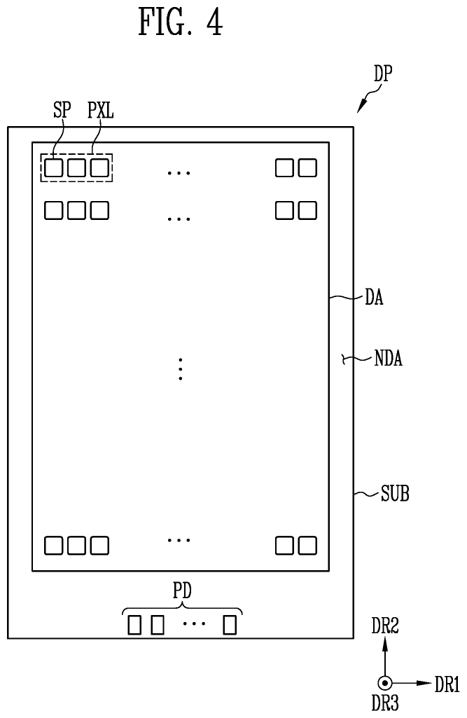

FIG. 4 illustrates a schematic top plan view of an embodiment of a display panel of FIG. 1.

Referring to FIG. 4, an embodiment DP of the display panel 110 of FIG. 1 may include a display area DA and a non-display area NDA. The display panel DP displays an image through the display area DA. The non-display area NDA may be disposed around the display area DA.

The display panel DP may include a substrate SUB, sub-pixels SP, and pads PD.

In case that the display panel DP is used as a display screen for a head mounted display (HMD), a virtual reality (VR) device, a mixed reality (MR) device, or an augmented reality (AR) device, the display panel DP may be positioned very close to the user's eyes. For example, the sub-pixels SP with relatively high integration may be required. In order to increase the integration of the sub-pixels SP, the substrate SUB may be provided as a silicon substrate. The sub-pixels SP and/or the display panel DP may be formed on the substrate SUB, which is a silicon substrate. The display device 100 (see FIG. 1) including the display panel DP formed on the substrate SUB, which is a silicon substrate, may be referred to as an OLED on silicon (OLEDoS) display device.

The sub-pixels SP may be disposed in the display area DA on the substrate SUB. The sub-pixels SP may be arranged in a matrix format in a first direction DR1 and a second direction DR2 that intersects the first direction DR1. However, embodiments are not limited thereto. For example, the sub-pixels SP may be arranged in a zigzag form in the first direction DR1 and the second direction DR2. For example, the sub-pixels SP may be disposed in a Pentile® shape. The first direction DR1 may be a row direction, and the second direction DR2 may be a column direction.

Two or more of multiple sub-pixels SP may configure one pixel PXL.

A constituent element to control the sub-pixels SP may be disposed in the non-display area NDA on the substrate SUB. For example, wires electrically connected to the sub-pixels SP such as the first to m-th gate lines GL1 to GLm and the first to n-th data lines DL1 to DLn of FIG. 1, may be disposed in the non-display area NDA.

At least one of the gate driver 120, the data driver 130, the voltage generator 140, the controller 150 and the temperature sensor 160 in FIG. 1 may be integrated in the non-display area NDA of the display panel DP. The gate driver 120 of FIG. 1 may be mounted on the display panel DP, and may be disposed in the non-display area NDA. In other embodiments, the gate driver 120 may be implemented as an integrated circuit separated from the display panel DP. The temperature sensor 160 may be disposed in the non-display area NDA to detect the temperature of the display panel DP.

The pads PD may be disposed in the non-display area NDA on the substrate SUB. The pads PD may be electrically connected to the sub-pixels SP through wires. For example, the pads PD may be electrically connected to the sub-pixels SP through the first to n-th data lines DL1 to DLn.

The pads PD may interface the display panel DP to other constituent elements of the display device 100 (see FIG. 1). Voltages and signals required for operations of constituent elements included in the display panel DP may be provided from the driver integrated circuit DIC of FIG. 1 through the pads PD. For example, the first to n-th data lines DL1 to DLn may be electrically connected to the driver integrated circuit DIC through the pads PD. For example, the first and second power voltages VDD and VSS may be received from the driver integrated circuit DIC through the pads PD. For example, in case that the gate driver 120 is mounted on the display panel DP, the gate control signal GCS may be transmitted from the driver integrated circuit DIC to the gate driver 120 through the pads PD.

The display area DA may have various shapes. The display area DA may have a closed-loop shape including sides of a straight line and/or a curved line. For example, the display area DA may have shapes such as a polygonal shape, a circular shape, a semicircular, and an elliptical shape.

The display panel DP may have a flat display surface. In other embodiments, the display panel DP may have a display surface that may be at least partially round. The display panel DP may be bendable, foldable, or rollable. For example, the display panel DP and/or the substrate SUB may include materials with flexible properties.

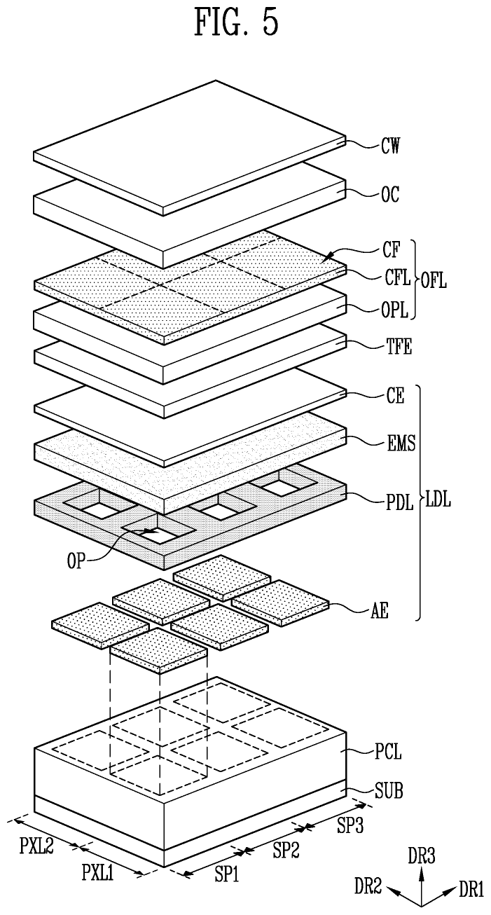

FIG. 5 illustrates an exploded schematic perspective view of a portion of a display panel of FIG. 4. As depicted in FIG. 5, for clear and concise description, a portion of the display panel DP corresponding to two pixels PXL1 and PXL2 among the pixels PXL of FIG. 4 is schematically shown. Portions of the display panel DP corresponding to the remaining pixels may be similarly configured.

Referring to FIG. 5, each of first and second pixels PXL1 and PXL2 may include first to third sub-pixels SP1, SP2, and SP3. However, embodiments are not limited thereto. For example, each of the first and second pixels PXL1 and PXL2 may include four sub-pixels, or two sub-pixels.

As depicted in FIG. 5, the first to third sub-pixels SP1, SP2, and SP3 may have quadrangular shapes and have the same sizes in case that viewed in the third direction DR3 (or in a plan view) crossing the first and second directions DR1 and DR2. However, embodiments are not limited thereto. The first to third sub-pixels SP1, SP2, and SP3 may be modified to have various shapes in a plan view.

The display panel DP may include a substrate SUB, a pixel circuit layer PCL, a light emitting element layer LDL, an encapsulation layer TFE, an optical functional layer OFL, an overcoat layer OC, and a cover window CW. For example, the substrate SUB, the pixel circuit layer PCL, the light emitting element layer LDL, the encapsulation layer TFE, the optical functional layer OFL, the overcoat layer OC, and the cover window CW may be sequentially disposed in the third direction DR3 (e.g., thickness direction).

The substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, an epitaxial layer, a silicon on Insulator (SOI) layer, or a semiconductor on insulator (SeOI) layer. In other embodiments, the substrate SUB may include a glass substrate. In other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may function as at least some of circuit elements, wires, and the like.

The conductive patterns may include copper, but embodiments are not limited thereto.

The circuit elements may include the sub-pixel circuit SPC (see FIG. 2) for each of first to third sub-pixels SP1, SP2, and SP3. The sub-pixel circuit SPC may include transistors and one or more capacitors. Each transistor may include a semiconductor portion including a source region, a drain region, and a channel region, and a gate electrode overlapping the semiconductor portion. In case that the substrate SUB is provided as a silicon substrate, the semiconductor portion may be included in the substrate SUB, and the gate electrode may be included in the pixel circuit layer PCL as the conductive pattern of the pixel circuit layer PCL. In case that the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 (e.g., thickness direction) with an insulating layer therebetween.

The wires of the pixel circuit layer PCL may include signal lines electrically connected to each of the first to third sub-pixels SP1, SP2, and SP3 for example, a gate line, a light emitting control line, and a data line. The wires may further include the wire electrically connected to the first power voltage node VDDN of FIG. 2. The wires may further include the wire electrically connected to the second power voltage node VSSN of FIG. 2.

The light emitting element layer LDL may include anode electrodes AE (or first electrode), a pixel defining layer PDL, a light emitting structure (or light emitting member) EMS, and a cathode electrode CE (or second electrode).

The anode electrodes AE may be disposed on the pixel circuit layer PCL. The anode electrodes AE may contact circuit elements of the pixel circuit layer PCL. The anode electrodes AE may include an opaque conductive material capable of reflecting light, but embodiments are not limited thereto.

The pixel defining layer PDL may be disposed on the anode electrodes AE. The pixel defining layer PDL may include an opening OP exposing a portion of each of the anode electrodes AE. Each of light emitting areas respectively corresponding to each of the first to third sub-pixels SP1 to SP3 may be defined by the opening OP of the pixel defining layer PDL. For example, each of the light emitting areas respectively corresponding to each of the first to third sub-pixels SP1 to SP3 may be defined by the anode electrodes AE. In an area adjacent to the boundary of neighboring sub-pixels, the pixel defining layer PDL may include a separator causing a discontinuity to be formed in the light emitting structure EMS. For example, each of the light emitting areas respectively corresponding to each of the first to third sub-pixels SP1 to SP3 may be defined by the separators of the pixel defining layer PDL.

The pixel defining layer PDL may include an inorganic material. For example, the pixel defining layer PDL may include multiple stacked inorganic layers. For example, the pixel defining layer PDL may include a silicon oxide (SiOₓ) and a silicon nitride (SiNₓ). In other embodiments, the pixel defining layer PDL may include an organic material. However, the material of the pixel defining layer PDL is not limited thereto.

The light emitting structure EMS may be disposed on the anode electrodes AE exposed by the opening OP of the pixel defining layer PDL. The light emitting structure EMS may include a light emitting layer to generate light, an electron transport layer that transports electrons and a hole transport layer that transports holes.

The light emitting structure EMS may fill the opening OP of the pixel defining layer PDL, and may be disposed (e.g., entirely disposed) on an upper portion of the pixel defining layer PDL. For example, the light emitting structure EMS may extend across the first to third sub-pixels SP1 to SP3. For example, at least some of the functional layers in the light emitting structure EMS may be separated or bent at the boundaries between the first to third sub-pixels SP1 to SP3. However, embodiments are not limited thereto. For example, portions of the light emitting structure EMS corresponding to the first to third sub-pixels SP1 to SP3 may be separated from each other, and each of the portions of the light emitting structure EMS may be disposed in the opening OP of the pixel defining layer PDL.

The cathode electrode CE may be disposed on the light emitting structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may be a thin metal layer with a thickness sufficient to transmit light emitted from the light emitting structure EMS. The cathode electrode CE may be made of a metallic material or a transparent conductive material to have a relatively thin thickness. The cathode electrode CE may include at least one of various transparent conductive materials including an indium tin oxide, an indium zinc oxide, an indium tin zinc oxide, an aluminum zinc oxide, a gallium zinc oxide, a zinc tin oxide, and a gallium tin oxide. In other embodiments, the cathode electrode CE may include at least one of silver (Ag), magnesium (Mg) and a mixture thereof. However, the material of the cathode electrode CE is not limited thereto.

One of the anode electrodes AE, the portion of the light emitting structure EMS overlapping the anode electrodes AE, and the portion of the cathode electrode CE overlapping the anode electrodes AE may configure one light emitting element LD (see FIG. 2). For example, each of the light emitting elements of the first to third sub-pixels SP1 to SP3 may include one anode electrode, a portion of the light emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light emitting layer of the light emitting structure EMS to form excitons, and in case that the excitons transition from the excited state to the ground state, light may be generated. The luminance of light may be determined depending on the amount of current flowing through the light emitting layer. Depending on the configuration of the light emitting layer, the wavelength range of the generated light may be determined.

The encapsulation layer TFE may be disposed on the cathode electrode CE. The encapsulation layer TFE may cover the light emitting element layer LDL and/or the pixel circuit layer PCL. The encapsulation layer TFE may prevent oxygen and/or moisture from penetrating into the light emitting element layer LDL. The encapsulation layer TFE may include a structure in which one or more inorganic films and one or more organic films may be alternately stacked. For example, the inorganic film may include a silicon nitride (SiNₓ), a silicon oxide (SiOₓ), or a silicon oxynitride (SiOₓN_{y}). For example, the organic film may include an organic insulating material such as an acrylic resin, an epoxy resin, a phenol resin, a polyamide resin, a polyimide resin, an unsaturated polyesters resin, a polyphenylenethers resin, a polyphenylenesulfides resin, or a benzocyclobutene. However, the materials of the organic film and the inorganic film of the encapsulation layer TFE are not limited thereto.

The encapsulation layer TFE may further include a thin film containing an aluminum oxide (AlOₓ) in order to improve the encapsulation efficiency of the encapsulation layer TFE. The thin film containing an aluminum oxide may be disposed on the upper surface of the encapsulation layer TFE facing the optical functional layer OFL and/or the lower surface of the encapsulation layer TFE facing the light emitting element layer LDL.

The optical functional layer OFL may be disposed on the encapsulation layer TFE. The optical functional layer OFL may include an optical layer OPL and a color filter layer CFL.

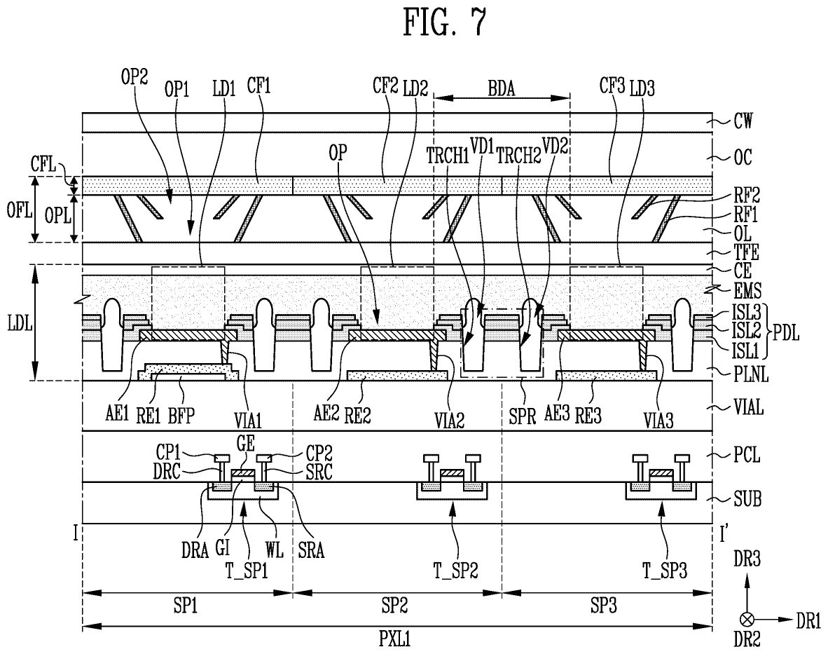

The optical layer OPL may be disposed between the encapsulation layer TFE and the color filter layer CFL. The optical layer OPL may include reflective layers corresponding to the first to third sub-pixels SP1 to SP3, respectively. Each of the reflective layers may improve light efficiency by reflecting light emitted from the light emitting structure EMS in an intended path to control the light emission direction. A detailed description of the optical layer OPL will be described later with reference to FIG. 7 to FIG. 12.

The color filter layer CFL may be disposed on the optical layer OPL. The color filter layer CFL may be selectively output light in a wavelength range or color corresponding to each sub-pixel by filtering light emitted from the light emitting structure EMS. The color filter layer CFL may include color filters CF respectively corresponding to the first to third sub-pixels SP1 to SP3), and each of the color filters CF may pass light in a wavelength range corresponding to the sub-pixel. For example, a color filter corresponding to the first sub-pixel SP1 may pass red light, a color filter corresponding to the second sub-pixel SP2 may pass green light, and a color filter corresponding to the third sub-pixel SP3 may pass blue light. At least some of the color filters CF may be omitted according to light emitted from the light emitting structure EMS of each sub-pixel.

The overcoat layer OC may be disposed on the color filter layer CFL. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign substances such as dust and moisture. For example, the overcoat layer OC may include at least one of an inorganic insulating film and an organic insulating film. For example, the overcoat layer OC may include epoxy, but embodiments are not limited thereto.

The cover window CW may be disposed on the overcoat layer OC. The cover window CW may protect lower layers thereof. The cover window CW may have a higher refractive index than the overcoat layer OC. The cover window CW may include glass, but embodiments are not limited thereto. For example, the cover window CW may be an encapsulation glass that protects constituent elements disposed thereunder. In other embodiments, the cover window CW may be omitted.

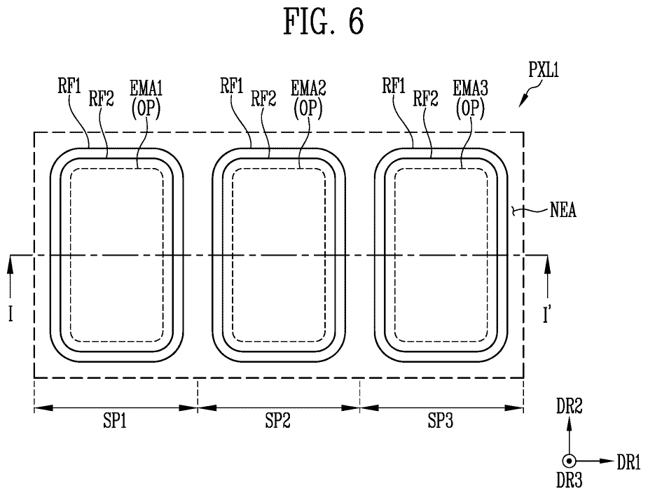

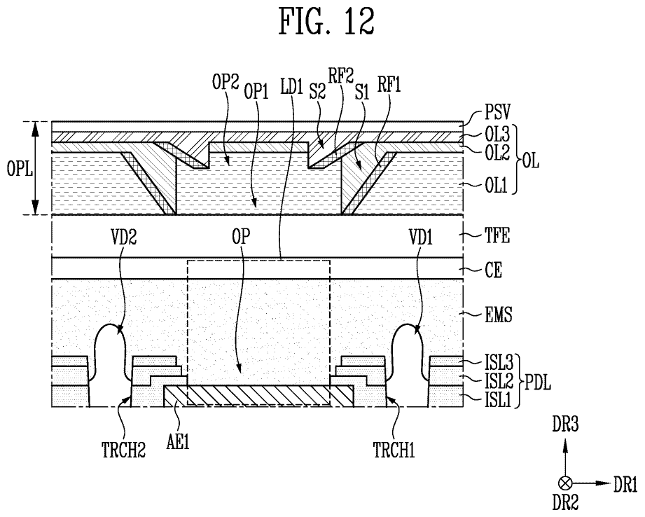

FIG. 6 illustrates a schematic top plan view of one of pixels of FIG. 5 according to an embodiment. FIG. 7 to FIG. 11 illustrate schematic cross-sectional views taken along line I-I′ of FIG. 6 according to an embodiment of the disclosure. FIG. 12 illustrates an enlarged schematic view of reflective layers of FIG. 7 according to an embodiment.

For a clear and concise description in FIG. 6, the first pixel PXL1 among the first and second pixels PXL1 and PXL2 of FIG. 5 is schematically illustrated. The remaining pixels may be similarly configured to the first pixel PXL1.

Referring to FIG. 5 and FIG. 6, a first pixel PXL1 may include the first to third sub-pixels SP1 to SP3 disposed in the first direction DR1.

The first sub-pixel SP1 may include a first light emitting area EMA1 and a non-light emitting area NEA around the first light emitting area EMA1. The second sub-pixel SP2 may include a second light emitting area EMA2 and the non-light emitting area NEA around the second light emitting area EMA2. The third sub-pixel SP3 may include a third light emitting area EMA3 and the non-light emitting area NEA around the third light emitting area EMA3.

The first light emitting area EMA1 may be an area in which light is emitted from a portion of the light emitting structure EMS (see FIG. 5) corresponding to the first sub-pixel SP1. The second light emitting area EMA2 may be an area in which light is emitted from a portion of the light emitting structure EMS corresponding to the second sub-pixel SP2. The third light emitting area EMA3 may be an area in which light is emitted from a portion of the light emitting structure EMS corresponding to the third sub-pixel SP3.

The reflective layers RF1 and RF2 may be disposed to correspond to the first to third sub-pixels SP1 to SP3, respectively. The planar shapes of the reflective layers RF1 and RF2 may follow the planar shapes of the first to third light emitting areas EMA1 to EMA3, respectively. For example, the planar shapes of the reflective layers RF1 and RF2 may be similar to the planar shapes of the first to third light emitting areas EMA1 to EMA3, respectively.

The size (or planar area) of the first reflective layer RF1 may be greater than the sizes (or planar areas) of the first to third light emitting areas EMA1 to EMA3. The width of the first reflective layer RF1 in the first direction DR1 and/or the second direction DR2 may be greater than the width of the first to third light emitting areas EMA1 to EMA3 in the first direction DR1 and/or the second direction DR2.

The size (or planar area) of the first reflective layer RF1 may be greater than the size (or planar area) of the opening OP of the pixel defining layer PDL. The width of the first reflective layer RF1 in the first direction DR1 and/or the second direction DR2 may be greater than the width of the opening OP of the pixel defining layer PDL in the first direction DR1 and/or the second direction DR2.

The size (or planar area) of the second reflective layer RF2 may be greater than the sizes of the first to third light emitting areas EMA1 to EMA3. The width of the second reflective layer RF2 in the first direction DR1 and/or the second direction DR2 may be greater than the width of the first to third light emitting areas EMA1 to EMA3 in the first direction DR1 and/or the second direction DR2.

The size (or planar area) of the second reflective layer RF2 may be greater than the size (or planar area) of the opening OP of the pixel defining layer PDL. The width of the second reflective layer RF2 in the first direction DR1 and/or the second direction DR2 may be greater than the width of the opening OP of the pixel defining layer PDL in the first direction DR1 and/or the second direction DR2.

The size (or planar area) of the first reflective layer RF1 may be greater than the size (or planar area) of the second reflective layer RF2. The width of the first reflective layer RF1 in the first direction DR1 and/or the second direction DR2 may be greater than the width of the second reflective layer RF2 in the first direction DR1 and/or the second direction DR2.

Referring to FIG. 7, the substrate SUB and the pixel circuit layer PCL disposed on the substrate SUB may be provided.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements for each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (see FIG. 2) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. As depicted in FIG. 7, for clear and concise description, one of the transistors of each sub-pixel is shown and the remaining circuit elements are omitted.

The transistor T_SP1 of the first sub-pixel SP1 may include a source area SRA, a drain area DRA, and a gate electrode GE which may be disposed between the source area SRA and the drain area DRA.

The source area SRA and the drain area DRA may be disposed in the substrate SUB. A well WL formed through an ion injection process may be disposed in the substrate SUB, and the source area SRA and the drain area DRA may be disposed to be spaced apart from each other in the well WL. The area between the source area SRA and the drain area DRA in the well WL may be defined as a channel area. The gate electrode GE overlaps the channel area between the source area SRA and the drain area DRA in the third direction DR3 (e.g., thickness direction), and may be disposed on the pixel circuit layer PCL. The gate electrode GE may be separated from the well WL or the channel area by an insulating material such as a gate insulating layer GI. The gate electrode GE may include a conductive material.

Multiple layers included in the pixel circuit layer PCL include insulating layers and conductive patterns disposed between the insulating layers, and the conductive patterns may include first and second conductive patterns CP1 and CP2. The first conductive pattern CP1 may be electrically connected to the drain area DRA through a drain connection portion DRC penetrating one or more insulating layers. The second conductive pattern CP2 may be electrically connected to the source area SRA through a source connection portion SRC penetrating one or more insulating layers.

As the gate electrode GE and the first and second conductive patterns CP1 and CP2 may be electrically connected to other circuit elements and/or wires, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be similarly configured to the transistor T_SP1 of the first sub-pixel SP1.

As described above, the substrate SUB and the pixel circuit layer PCL may include circuit elements for each of the first to third sub-pixels SP1 to SP3.

A via layer VIAL may be disposed on the pixel circuit layer PCL. The via layer VIAL may cover the pixel circuit layer PCL, and may have an overall flat surface. The via layer VIAL may flatten steps on the pixel circuit layer PCL. The via layer VIAL may include at least one of a silicon oxide (SiOₓ), a silicon nitride (SiNₓ), and a silicon carbon nitride (SiCN), but embodiments are not limited thereto.

The light emitting element layer LDL may be disposed on the via layer VIAL. The light emitting element layer LDL may include first to third reflective electrodes RE1 to RE3, a planarization layer PLNL, first to third anode electrodes AE1 to AE3, a pixel defining layer PDL, a light emitting structure EMS, and a cathode electrode CE.

The first to third reflective electrodes RE1 to RE3 may be disposed in the first to third sub-pixels SP1 to SP3 on the via layer VIAL, respectively. Each of the first to third reflective electrodes RE1 to RE3 may contact a circuit element disposed on the pixel circuit layer PCL through a via penetrating the via layer VIAL.

The first to third reflective electrodes RE1 to RE3 may function as full mirrors that reflect light emitted from the light emitting structure EMS toward the display surface (or the cover window CW). The first to third reflective electrodes RE1 to RE3 may include metallic materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti) and an alloy of two or more materials selected therefrom, but embodiments are not limited thereto.

A connection electrode may be disposed below each of the first to third reflective electrodes RE1 to RE3. The connection electrode may improve the electrical connection characteristics between the corresponding reflective electrode and the circuit element of the pixel circuit layer PCL. The connection electrode may have a multi-layered structure. The multi-layered structure may include titanium (Ti), a titanium nitride (TiN), a tantalum nitride (TaN), and the like, but embodiments are not limited thereto. A corresponding reflective electrode may be disposed between the multiple layers of the connecting electrode.

A buffer pattern BFP may be disposed below at least one of the first to third reflective electrodes RE1 to RE3 and disposed on the via penetrating the via layer VIAL. The buffer pattern BFP may include an inorganic material such as a silicon carbon nitride, but embodiments are not limited thereto. By disposing the buffer pattern BFP, the height of the corresponding reflective electrode in the third direction DR3 may be adjusted. For example, the buffer pattern BFP may be disposed between the first reflective electrode RE1 and the via layer VIAL to adjust the height of the first reflective electrode RE1.

The first to third reflective electrodes RE1 to RE3 may function as full mirrors, and the cathode electrode CE may function as a half mirror. For example, each of the first to third reflection electrodes RE1 to RE3 and the cathode electrode CE may provide a resonance structure in a corresponding sub-pixel. Light emitted from the light emitting layer of the light emitting structure EMS may be amplified by reciprocating between the reflective electrode and the cathode electrode CE, and the amplified light may be output through the cathode electrode CE. As such, the distance between each reflective electrode and the cathode electrode CE may be understood as the resonance distance for the light emitted from the light emitting layer of the corresponding light emitting structure EMS.

The first sub-pixel SP1 may have a shorter resonance distance than other sub-pixels due to the buffer pattern BFP. The resonance distance adjusted in this way may allow light in a specific wavelength range (for example, red color) to be effectively and efficiently amplified. Accordingly, the first sub-pixel SP1 may effectively and efficiently output light in the corresponding wavelength range.

As depicted in FIG. 7, the buffer pattern BFP is shown to be provided in the first sub-pixel SP1 and not in the second and third sub-pixels SP2 and SP3, but the embodiments are not limited thereto. The buffer pattern may be also provided in at least one of the second and third sub-pixels SP2 and SP3 so that the resonance distance of at least one of the second and third sub-pixels SP2 and SP3 may be adjusted. For example, the first to third sub-pixels SP1 to SP3 may correspond to red, green, and blue, respectively, the distance between the first reflective electrode RE1 and the cathode electrode CE in the third direction DR3 (e.g., thickness direction) may be shorter than the distance between the second reflective electrode RE2 and the cathode electrode CE, and the distance between the second reflective electrode RE2 and the cathode electrode CE may be shorter than the distance between the third reflective electrode RE3 and the cathode electrode CE.

To planarize the steps between the first to third reflective electrodes RE1 to RE3, the planarization layer PLNL may be disposed on the via layer VIAL to cover the first to third reflective electrodes RE1 to RE3. The planarization layer PLNL may cover (e.g., entirely cover) the first to third reflective electrodes RE1 to RE3 and the via layer VIAL, and may have a flat surface. The planarization layer PLNL may be omitted.

The first to third anode electrodes AE1 to AE3 respectively overlapping the first to third reflective electrodes RE1 to RE3 may be disposed on the planarization layer PLNL. The first to third anode electrodes AE1 to AE3 may have shapes similar to the first to third light emitting areas EMA1 to EMA3 of FIG. 6 in case that viewed in the third direction DR3 (or in a plan view). The first to third anode electrodes AE1 to AE3 may be respectively and electrically connected to the first to third reflective electrodes RE1 to RE3. The first anode electrode AE1 may be electrically connected to the first reflective electrode RE1 through the first via VIA1 penetrating the planarization layer PLNL. The second anode electrode AE2 may be electrically connected to the second reflective electrode RE2 through the second via VIA2 penetrating the planarization layer PLNL. The third anode electrode AE3 may be electrically connected to the third reflective electrode RE3 through the third via VIA3 penetrating the planarization layer PLNL.

The first to third anode electrodes AE1 to AE3 may include at least one of a transparent conductive material such as an indium tin oxide (ITO), an indium zinc oxide (IZO), a zinc oxide (ZnOx), an indium gallium zinc oxide (IGZO), and an indium tin zinc oxide (ITZO). However, the materials of the first to third anode electrodes AE1 to AE3 are not limited thereto. For example, the first to third anode electrodes AE1 to AE3 may include a titanium nitride.

The pixel defining layer PDL may be disposed on some of the first to third anode electrodes AE1 to AE3 and the planarization layer PLNL. The pixel defining layer PDL has an opening OP exposing a portion of each of the first to third anode electrodes AE1 to AE3. An area overlapping the pixel defining layer PDL may be understood as the boundary area BDA between adjacent sub-pixels.

The pixel defining layer PDL may include multiple inorganic insulating layers. Each of multiple inorganic insulating layers may include at least one of a silicon oxide (SiOₓ) and a silicon nitride (SiNₓ). For example, the pixel defining layer PDL may include a first inorganic insulating layer ISL1, a second inorganic insulating layer ISL2 and a third inorganic insulating layer ISL3 sequentially stacked. The first to third inorganic insulating layers ISL1 to ISL3 may include a silicon oxide (SiOₓ) and a silicon nitride (SiNₓ), but embodiments are not limited thereto. The first to third inorganic insulating layers ISL1 to ISL3 may have a step-shaped cross-section in an area adjacent to the opening OP.

The pixel defining layer PDL may include a separator SPR in the boundary area BDA between adjacent sub-pixels. For example, the separator SPR may be provided in each of the boundary areas between the sub-pixels SP in FIG. 4.

The separator SPR may cause a discontinuity to be formed in the light emitting structure EMS in the boundary area BDA. For example, the light emitting structure EMS may be disconnected bent in the boundary area BDA by the separator SPR. Accordingly, the first to third light emitting areas EMA1 to EMA3 of FIG. 6 respectively corresponding to the first to third sub-pixels SP1 to SP3 may be defined according to the separator SPR of the pixel defining layer PDL.

The separator SPR may be provided in or on the pixel defining layer PDL. The pixel defining layer PDL may include one or more trenches TRCH1 and TRCH2 as the separator SPR in the boundary area BDA. As shown in FIG. 7, one or more trenches TRCH1 and TRCH2 may penetrate the pixel defining layer PDL and partially penetrate the planarization layer PLNL. In other embodiments, one or more trenches TRCH1 and TRCH2 may penetrate the pixel defining layer PDL and the planarization layer PLNL, and may partially penetrate the via layer VIAL. In other embodiments, one or more trenches TRCH1 and TRCH2 at least partially penetrate the planarization layer PLNL and/or the via layer VIAL, and a portion of the pixel defining layer PDL may be disposed in one or more trenches TRCH1 and TRCH2.

As depicted in FIG. 7, two trenches TRCH1 and TRCH2 may be provided in the boundary area BDA. However, embodiments are not limited thereto. For example, the pixel defining layer PDL may include one trench in the boundary area BDA. For example, the pixel defining layer PDL may include three or more trenches in the boundary area BDA.

Due to the first and second trenches TRCH1 and TRCH2, discontinuous portions such as the first void VD1 and the second void VD2 may be formed in the light emitting structure EMS in the boundary area BDA. Some of multiple layers stacked in the light emitting structure EMS may be disconnected or bent by the first and second voids VD1 and VD2. For example, at least one charge generation layer and at least one hole injection layer included in the light emitting structure EMS may be disconnected in the first and second voids VD1 and VD2. As described above, due to the first and second trenches TRCH1 and TRCH2, the portions of the light emitting structure EMS included in the first to third sub-pixels SP1 to SP3 may be at least partially separated.

Depending on the shapes of the first and second trenches TRCH1 and TRCH2, the discontinuities formed in the light emitting structure EMS may vary.

The light emitting structure EMS may be formed through processes such as vacuum deposition or inkjet printing. For example, the same materials as the light emitting structure EMS may be disposed on the bottom surfaces of the first and second trenches TRCH1 and TRCH2 adjacent to the via layer VIAL.

The pixel defining layer PDL may include an additional separator so that the light emitting structure EMS may further include a discontinuous portion adjacent to the boundary area BDA. The uppermost third inorganic insulating layer ISL3 among the first to third inorganic insulating layers ISL1 to ISL3 of the pixel defining layer PDL may have a wider width than the second inorganic insulating layer ISL2 disposed directly below the third inorganic insulating layer. For example, the pixel defining layer PDL may have a cross-section of a “T” shape or “I” shape in the boundary area BDA. Depending on the shape of the pixel defining layer PDL, multiple layers included in the light emitting structure EMS may be at least partially disconnected or bent in the boundary area BDA or in an area adjacent to the boundary area BDA.

The light emitting structure EMS may be disposed on the anode electrodes AE exposed by the opening OP of the pixel defining layer PDL. The light emitting structure EMS may fill the opening OP of the pixel defining layer PDL, and may be disposed across (e.g., entirely across) the first to third sub-pixels SP1 to SP3. As described above, the light emitting structure EMS may be at least partially disconnected or bent in the boundary area BDA by the separator SPR. Accordingly, in case that the display panel DP operates, the current leaking from each of the first to third sub-pixels SP1 to SP3 to the neighboring sub-pixel through the layers included in the light emitting structure EMS may decrease. Accordingly, the first to third light emitting elements LD1 to LD3 may operate with relatively high reliability.

The cathode electrode CE may be disposed on the light emitting structure EMS. The cathode electrode CE may be commonly provided for the first to third sub-pixels SP1 to SP3. The cathode electrode CE may function as a half mirror that partially transmits and partially reflects light emitted from the light emitting structure EMS.

The first anode electrode AE1, the portion of the light emitting structure EMS overlapping the first anode electrode AE1, and the portion of the cathode electrode CE overlapping the first anode electrode AE1 may configure the first light emitting element LD1. The second anode electrode AE2, the portion of the light emitting structure EMS overlapping the second anode electrode AE2, and the portion of the cathode electrode CE overlapping the second anode electrode AE2 may configure the second light emitting element LD2. The third anode electrode AE3, the portion of the light emitting structure EMS overlapping the third anode electrode AE3, and the portion of the cathode electrode CE overlapping the third anode electrode AE3 may configure the third light emitting element LD3.

The encapsulation layer TFE may be disposed on the cathode electrode CE. The encapsulation layer TFE may prevent oxygen and/or moisture from penetrating into the light emitting element layer LDL.

The optical functional layer OFL may be disposed on the encapsulation layer TFE. The optical functional layer OFL may include an optical layer OPL and a color filter layer CFL.

The optical layer OPL may be disposed on the encapsulation layer TFE. The optical layer OPL may be disposed (e.g., directly disposed) on the encapsulation layer TFE. The optical layer OPL may include an organic layer OL and reflective layers RF1 and RF2 in the organic layer OL.

Each of the reflective layers RF1 and RF2 may control a light emission direction by reflecting light emitted from the first to third light emitting elements LD1 to LD3 in an intended path, thereby improving light efficiency.

The organic layer OL may be disposed on the encapsulation layer TFE. The organic layer OL may be disposed (e.g., directly disposed) on the encapsulation layer TFE. The refractive index of the organic layer OL may be different from the refractive index of the encapsulation layer TFE. For example, the refractive index of the organic layer OL may be greater than the refractive index of the encapsulation layer TFE. For example, the light emission efficiency may be improved by increasing light incident on the reflective layers RF1 and RF2.

The first reflective layer RF1 may be disposed in the organic layer OL. The first reflective layer RF1 may overlap the pixel defining layer PDL in the third direction DR3 (e.g., thickness direction). The first reflective layer RF1 may not overlap the opening OP of the pixel defining layer PDL in the third direction DR3 (e.g., thickness direction), but is not limited thereto.

The first reflective layer RF1 may function as a full mirror. Light emitted from the light emitting structure EMS may be reflected or at least partially reflected from the second reflective layer RF2 and incident on the first reflective layer RF1. Light incident on the first reflective layer RF1 may be reflected by the first reflective layer RF1 and emitted in the display direction of the display panel DP, for example, the front direction or the third direction DR3. Accordingly, stray light of the display panel DP may be reduced and light emission efficiency may be increased.

The first reflective layer RF1 may include a metallic material. For example, the first reflective layer RF1 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti) and an alloy of two or more materials selected therefrom, but embodiments are not limited thereto. In some embodiments, the first reflective layer RF1 may include a structure in which inorganic films are alternately stacked. For example, the first reflective layer RF1 may include a structure in which a silicon oxide (SiOₓ) and a titanium oxide (TiOₓ) are alternately stacked.

The second reflective layer RF2 may be disposed in the organic layer OL. The second reflective layer RF2 may be disposed on the first reflective layer RF1 in the organic layer OL. The second reflective layer RF2 may overlap the opening OP of the pixel defining layer PDL in the third direction DR3 (e.g., thickness direction). The second reflective layer RF2 may overlap the light emitting structure EMS in the third direction DR3 (e.g., thickness direction). For example, the second reflective layer RF2 may overlap the light emitting structure EMS disposed in the opening OP of the pixel defining layer PDL in the third direction DR3 (e.g., thickness direction). The second reflective layer RF2 may partially overlap the pixel defining layer PDL in the third direction DR3 (e.g., thickness direction), but is not limited thereto.

The second reflective layer RF2 may function as a half mirror that partially transmits and partially reflects light emitted from the light emitting structure EMS. Light emitted from the light emitting structure EMS may be partially reflected from the second reflective layer RF2 and incident on the first reflective layer RF1. Light incident on the first reflective layer RF1 may be reflected by the first reflective layer RF1 and emitted in the display direction of the display panel DP, for example, the front direction or the third direction DR3. Accordingly, stray light of the display panel DP may be reduced and light emission efficiency may be increased.

The second reflective layer RF2 may include a metallic material. For example, the second reflective layer RF2 may include at least one of various transparent conductive materials including an indium tin oxide, an indium zinc oxide, an indium tin zinc oxide, an aluminum zinc oxide, a gallium zinc oxide, a zinc tin oxide, and a gallium tin oxide. In other embodiments, the second reflective layer RF2 may include at least one of silver (Ag), magnesium (Mg) and a mixture thereof. The second reflective layer RF2 may include the same material as the first reflective layer RF1, but is not limited thereto.

The first reflective layer RF1 may include a first opening OP1. The second reflective layer RF2 may include a second opening OP2. The size (or diameter) of the first opening OP1 may be larger than the size (or diameter) of the second opening OP2 in a plan view. The width of the first opening OP1 in the first direction DR1 may be greater than the width of the second opening OP2 in the first direction DR1, but is not necessarily limited thereto. The size (or diameter) of the first opening OP1 may be larger than the size (or diameter) of the opening OP of the pixel defining layer PDL in a plan view. The width of the first opening OP1 in the first direction DR1 may be greater than the width of the opening OP of the pixel defining layer PDL in the first direction DR1, but is not necessarily limited thereto. The diameter of the second opening OP2 may be smaller than the diameter of the opening OP of the pixel defining layer PDL in a plan view. The width of the second opening OP2 in the first direction DR1 may be smaller than the width of the opening OP of the pixel defining layer PDL in the first direction DR1, but is not limited thereto.

The center of the first opening OP1 may be aligned with or coincide with the center of the opening OP of the pixel defining layer PDL. For example, the center of the first opening OP1 may overlap the center of the opening OP of the pixel defining layer PDL in a plan view, but is not limited thereto. The center of the second opening OP2 may be aligned with or coincide with the center of the opening OP of the pixel defining layer PDL. For example, the center of the second opening OP2 may overlap the center of the opening OP of the pixel defining layer PDL in a plan view, but is not limited thereto.

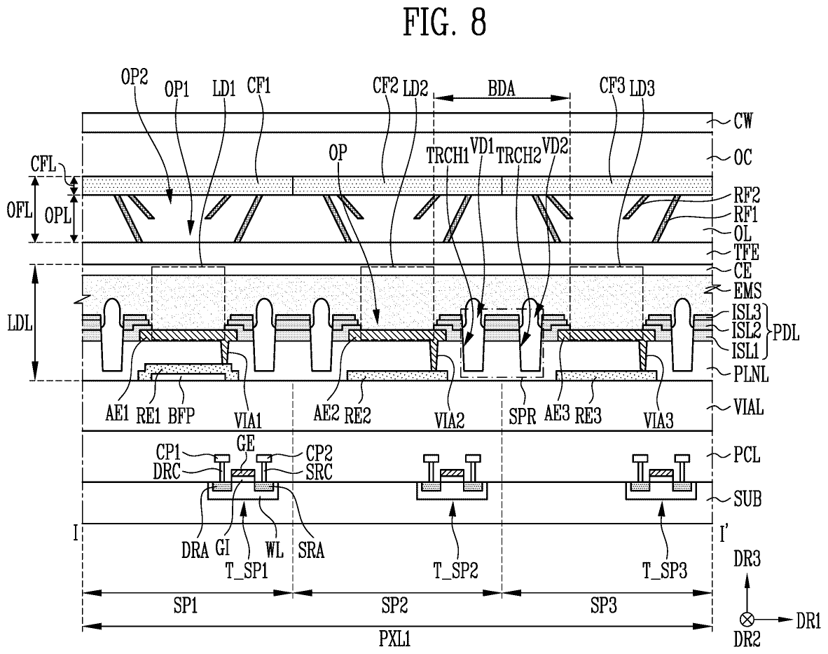

As shown in FIG. 8, the center of the second opening OP2 may be shifted from the center of the opening OP of the pixel defining layer PDL in a direction parallel to a plane defined by the first and second directions DR1 and DR2. For example, the center of the second opening OP2 may be shifted from the center of the opening OP of the pixel defining layer PDL in the planar direction. For example, light emitted from the light emitting structure EMS may be efficiently output in a direction inclined by a predetermined angle with respect to the normal direction of the display surface. As depicted in FIG. 8, an embodiment in which the center of the second opening OP2 is shifted from the center of the opening OP of the pixel defining layer PDL is illustrated, but the disclosure is not necessarily limited thereto, and the center of the first opening OP1 may be shifted from the center of the opening OP of the pixel defining layer PDL in consideration of the light emission direction.

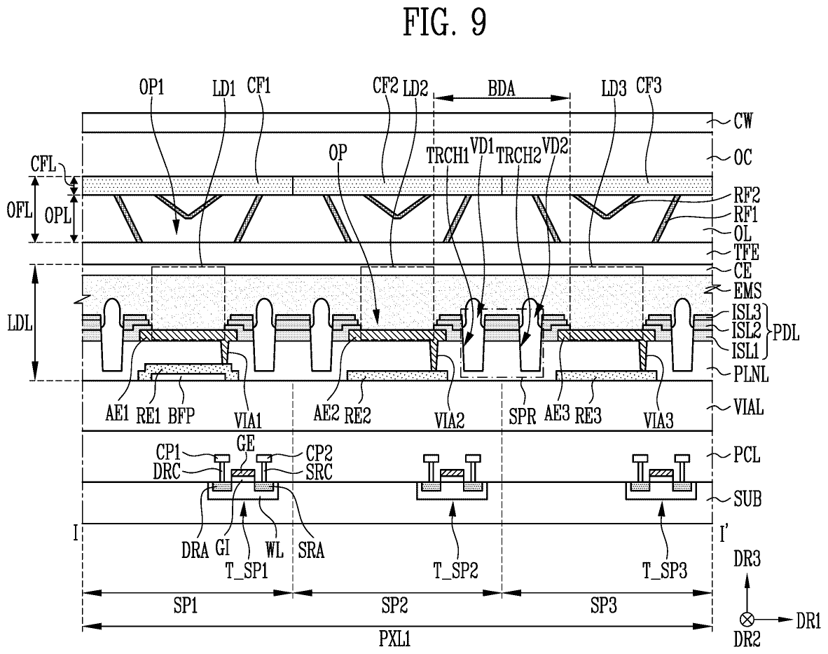

As shown in FIG. 9, the second reflective layer RF2 may not include an opening. For example, the second reflective layer RF2 may have a cone shape in a cross sectional view. As depicted in FIG. 9, an embodiment in which the second reflective layer RF2 does not include an opening is illustrated, but the disclosure is not limited thereto, and the first reflective layer RF1 may also not include an opening. For example, the first reflective layer RF1 may have a cone shape in a cross sectional view.

Each of the first reflective layer RF1 and/or the second reflective layer RF2 may include an inclined surface. An inclination angle of the inclined surface of the first reflective layer RF1 may be different from an inclination angle of the inclined surface of the second reflective layer RF2. Here, the inclination angle of each inclined surface may mean an angle formed by each inclined surface with respect to the substrate SUB. The inclination angle of the first reflective layer RF1 and/or the inclination angle of the second reflective layer RF2 may be variously changed in consideration of the light emission path of light emitted from the light emitting structure EMS.

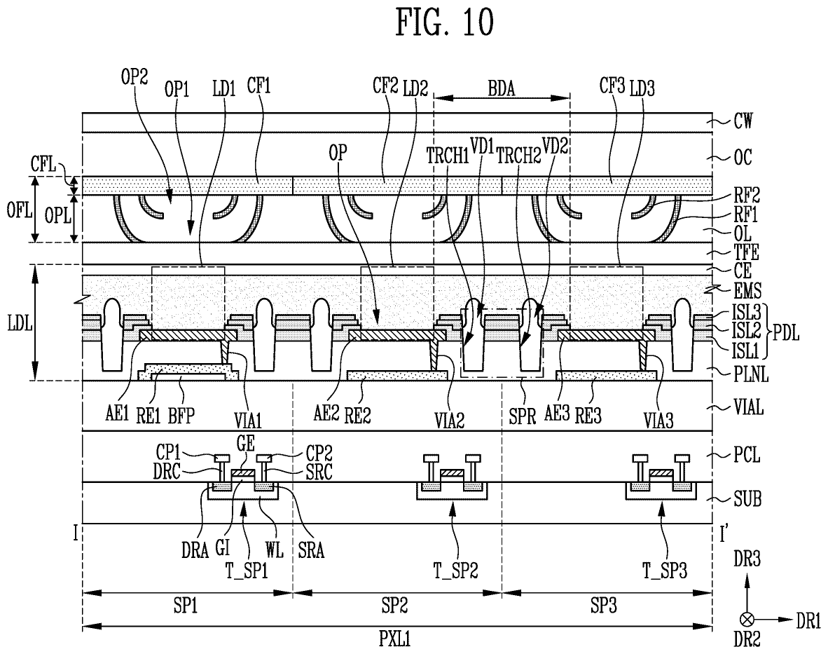

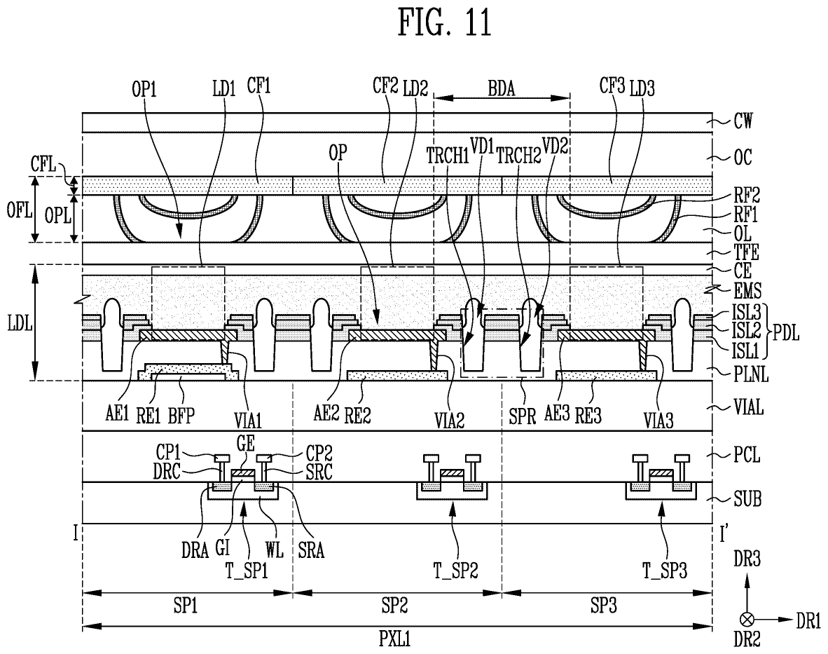

As shown in FIG. 10 and FIG. 11, the first reflective layer RF1 and/or the second reflective layer RF2 may include a spherical surface. The curvature of the spherical surface of the first reflective layer RF1 may be different from the curvature of the spherical surface of the second reflective layer RF2. The curvature of the first reflective layer RF1 and/or the curvature of the second reflective layer RF2 may be variously changed in consideration of the light emission path of light emitted from the light emitting structure EMS.

In some embodiments, one of the first reflective layer RF1 and the second reflective layer RF2 may include an inclined surface, and the other thereof may include a spherical surface.

As depicted in FIG. 10, an embodiment in which the first reflective layer RF1 includes the first opening OP1 and the second reflective layer RF2 includes the second opening OP2 is illustrated, but disclosure is not limited thereto. For example, as shown in FIG. 11, the second reflective layer RF2 may not include an opening. For example, the second reflective layer RF2 may have a hemispherical shape in a cross sectional view. In some embodiments, the first reflective layer RF1 may not include an opening. For example, the first reflective layer RF1 may have a hemispherical shape in a cross sectional view.

Referring to FIG. 12, the organic layer OL may include a first organic layer OL1, a second organic layer OL2, and/or a third organic layer OL3. The first organic layer OL1 may be disposed on the encapsulation layer TFE. The first organic layer OL1 may be disposed (e.g., directly disposed) on the encapsulation layer TFE. The second organic layer OL2 may be disposed on the first organic layer OL1. The second organic layer OL2 may be disposed (e.g., directly disposed) on the first organic layer OL1. The third organic layer OL3 may be disposed on the second organic layer OL2. The third organic layer OL3 may be disposed (e.g., directly disposed) on the second organic layer OL2.

The first organic layer OL1, the second organic layer OL2, and/or the third organic layer OL3 may include the same material. However, the disclosure is not necessarily limited thereto, and the first organic layer OL1, the second organic layer OL2, and/or the third organic layer OL3 may have different refractive indices. The optical layer OPL may function as a lens by controlling the refractive index of the first organic layer OL1, the second organic layer OL2, and/or the third organic layer OL3.

The first organic layer OL1, the second organic layer OL2, and/or the third organic layer OL3 may include an acrylic resin, an epoxy resin, a phenol resin, a polyamide resin, a polyimide resin, an unsaturated polyester resin, a polyphenyleneether resin, a polyphenylenesulfide resin, or benzocyclobutene (BCB), but are not necessarily limited thereto.

The first organic layer OL1 may include a first inclined surface S1. The first reflective layer RF1 may be disposed on the first inclined surface S1. The first reflective layer RF1 may be disposed between the first organic layer OL1 and the second organic layer OL2. The first reflective layer RF1 may be disposed (e.g., directly disposed) on the first organic layer OL1. The second organic layer OL2 may be disposed (e.g., directly disposed) on the first reflective layer RF1.

The second organic layer OL2 may include a second inclined surface S2. The second reflective layer RF2 may be disposed on the second inclined surface S2. The second reflective layer RF2 may be disposed between the second organic layer OL2 and the third organic layer OL3. The second reflective layer RF2 may be disposed (e.g., directly disposed) on the second organic layer OL2. The third organic layer OL3 may be disposed (e.g., directly disposed) on the second reflective layer RF2.

The first organic layer OL1 may be disposed in the first opening OP1 of the first reflective layer RF1. The second organic layer OL2 and/or the third organic layer OL3 may overlap the first opening OP1 in the third direction DR3 (e.g., thickness direction), but are not limited thereto.

The second organic layer OL2 may be disposed in the second opening OP2 of the second reflective layer RF2. In some embodiments, the first organic layer OL1 may be further disposed in the second opening OP2. The third organic layer OL3 may overlap the second opening OP2 in the third direction DR3 (e.g., thickness direction), but is not limited thereto.

In some embodiments, the optical layer OPL may further include a protective layer PSV. The passivation layer PSV may be disposed on the third organic layer OL3. The passivation layer PSV may be disposed (e.g., directly disposed) on the third organic layer OL3. The passivation layer PSV may include a silicon nitride (SiNₓ), a silicon oxide (SiOₓ), a silicon oxynitride (SiOₓN_{y}), or the like, but is not limited thereto.

According to the above-described embodiment, the light emission efficiency of the display panel DP may be improved by forming the optical layer OPL using the organic layer OL and the reflective layers RF1 and RF2.

Referring back to FIG. 7, the color filter layer CFL may be disposed on the optical layer OPL. The color filter layer CFL may include first to third color filters CF1 to CF3 corresponding to the first to third sub-pixels SP1 to SP3, respectively. The first to third color filters CF1 to CF3 may pass light in different wavelength ranges. For example, the first to third color filters CF1 to CF3 may pass red, green, and blue colored light, respectively.

The first to third color filters CF1 to CF3 may partially overlap in the boundary area BDA. In other embodiments, the first to third color filters CF1 to CF3 may be spaced apart from each other, and a black matrix may be provided between each of the first to third color filters CF1 to CF3.

The overcoat layer OC may be disposed on the color filter layer CFL. The overcoat layer OC may protect its lower layers from foreign substances such as dust, moisture, and the like. The cover window CW may be disposed on the overcoat layer OC.

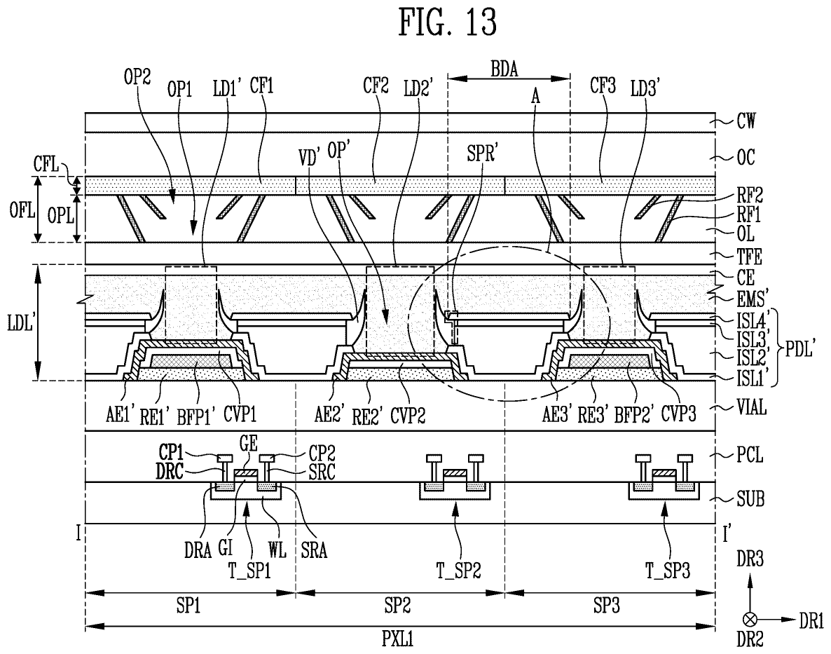

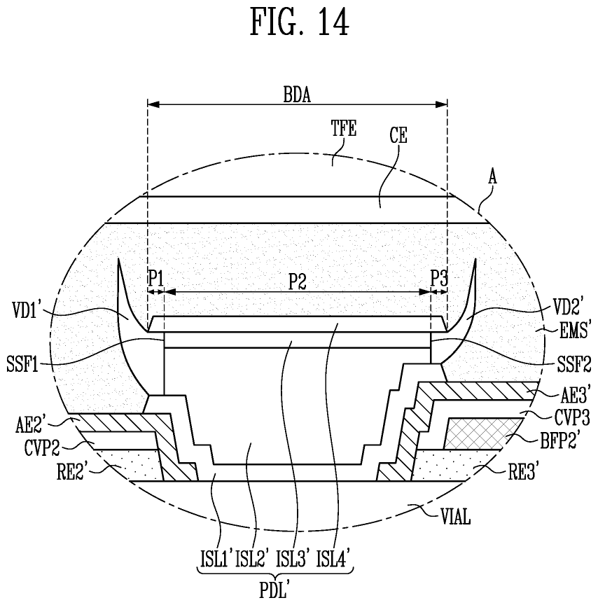

FIG. 13 illustrates a schematic cross-sectional view taken along line I-I′ of FIG. 6 according to another embodiment. FIG. 14 illustrates an enlarged schematic view of area “A” of FIG. 13.

Referring to FIG. 13, a pixel circuit layer PCL and a via layer VIAL may be disposed on a substrate SUB. The substrate SUB, the pixel circuit layer PCL, and the via layer VIAL of FIG. 13 may be similarly configured to the substrate SUB, the pixel circuit layer PCL, and the via layer VIAL of FIG. 7 and the like. Hereinafter, redundant descriptions thereof will be omitted.

A light emitting element layer LDL′ may be disposed on the via layer VIAL. The light emitting element layer LDL′ may include first to third reflective electrodes RE1′ to RE3′, first and second buffer patterns BFP1′ and BFP2′, first to third cover patterns CVP1 to CVP3, first to third anode electrodes AE1′ to AE3′, a pixel defining layer PDL′, a light emitting structure EMS′, and a cathode electrode CE.

The first to third reflective electrodes RE1′ to RE3′ may be disposed in the first to third sub-pixels SP1 to SP3 on the via layer VIAL, respectively. Each of the first to third reflective electrodes RE1′ to RE3′ may contact a circuit element disposed on the pixel circuit layer PCL through a via penetrating the via layer VIAL.

The first to third reflective electrodes RE1′ to RE3′ may reflect light emitted from the light emitting structure EMS' toward the display surface (or the cover window CW). The first to third reflective electrodes RE1′ to RE3′ may include metallic materials suitable for reflecting light. The first to third reflective electrodes RE1′ to RE3′ may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti) and an alloy of two or more materials selected therefrom, but embodiments are not limited thereto.

A connection electrode may be further provided between each of the first to third reflective electrodes REt′ to RE3′ and the via layer VIAL. The connection electrode may improve the electrical connection characteristics between the corresponding reflective electrode and the circuit element of the pixel circuit layer PCL. The connection electrode may have a multi-layered structure. The multi-layered structure may include titanium (Ti), aluminum (Al), a titanium nitride (TiN), a tantalum nitride (TaN), and the like, but embodiments are not limited thereto. A corresponding reflective electrode may be disposed between the multiple layers of the connecting electrode.

A buffer pattern may be disposed on at least one of the first to third reflective electrodes REt′ to RE3′. The first and second buffer patterns BFP1′ and BFP2′ may be disposed on the first and third reflection electrodes RE1′ and RE3′, respectively. Thicknesses of the first and third anode electrodes AE1′ and AE3′ from an upper portion of the via layer VIAL in the third direction DR3 (e.g., thickness direction) may be adjusted by changing thicknesses of the first and second buffer patterns BFP1′ and BFP2′ in the third direction DR3 (e.g., thickness direction), respectively. The first and second buffer patterns BFP1′ and BFP2′ may include an inorganic material such as a silicon oxide (SiOₓ) and a silicon nitride (SiNₓ), but embodiments are not limited thereto.

The first to third cover patterns CVP1 to CVP3 may be disposed on the first to third reflective electrodes RE1′ to RE3′, respectively. In the first sub-pixel SP1, the first cover pattern CVP1 may be disposed on the first reflective electrode RE1′ and the first buffer pattern BFP1′. In the second sub-pixel SP2, the second cover pattern CVP2 may be disposed on the second reflective electrode RE2′. In the third sub-pixel SP3, the third cover pattern CVP3 may be disposed on the third reflective electrode RE3′ and the second buffer pattern BFP2′. The first to third cover patterns CVP1 to CVP3 may be formed after the formation of the first and second buffer patterns BFP1′ and BFP2′ during the manufacturing process. The first to third cover patterns CVP1 to CVP3 may include the same material as the first and second buffer patterns BFP1′ and BFP2′. For example, the first to third cover patterns CVP1 to CVP3 may include inorganic materials such as a silicon oxide (SiOₓ) and a silicon nitride (SiNₓ), but embodiments are not limited thereto.

The first to third anode electrodes AE1′ to AE3′ may be disposed on the first to third cover patterns CVP1 to CVP3, respectively. The first anode electrode AE1′ may cover the first cover pattern CVP1, the first buffer pattern BFP1′, and the first reflection electrode RE1′. The second anode electrode AE2′ may cover the second cover pattern CVP2 and the second reflection electrode RE2′. The third anode electrode AE3′ may cover the third cover pattern CVP3, the second buffer pattern BFP2′, and the third reflective electrode RE3′.

The first to third anode electrodes AE1′ to AE3′ may be electrically connected to the first to third reflective electrodes RE1′ to RE3′, respectively. For example, each anode electrode may be electrically connected to an end (or edge) of the corresponding reflective electrode. However, embodiments are not limited thereto. In order to improve the electrical connection characteristics between the anode electrode and the reflective electrode, the anode electrode may be electrically connected to the reflective electrode in various ways.

The first to third anode electrodes AE1′ to AE3′ may include at least one of a transparent conductive materials such as an indium tin oxide (ITO), an indium zinc oxide (IZO), a zinc oxide (ZnOx), an indium gallium zinc oxide (IGZO), and an indium tin zinc oxide (ITZO). However, the materials of the first to third anode electrodes AE1′ to AE3′ are not limited thereto. For example, the first to third anode electrodes AE1′ to AE3′ may include a titanium nitride.

The first to third anode electrodes AE1′ to AE3′ may have shapes similar to the first to third light emitting areas EMA1 to EMA3 of FIG. 6 in case that viewed in the third direction DR3 (or in a plan view).

The first to third anode electrodes AE1′ to AE3′ and the cathode electrode CE may reflect or at least partially reflect incident light. Light emitted from the light emitting layer of the light emitting structure EMS' may be amplified by reciprocating between the anode electrode and the cathode electrode CE, and may be output through the cathode electrode CE. For example, each anode electrode and the cathode electrode CE may provide a resonance structure in a corresponding sub-pixel. For example, the distance between each anode electrode and the cathode electrode CE may be understood as the resonance distance for the light emitted from the light emitting layer of the corresponding light emitting structure EMS.

The first to third sub-pixels SP1 to SP3 may correspond to red, green and blue, respectively. For example, thicknesses of the first and third anode electrodes AE1′ and AE3′ in the third direction DR3 (e.g., thickness direction) may be greater than the second anode electrode AE2′ by the first and second buffer patterns BFP1′ and BFP2′. Accordingly, the first and third sub-pixels SP1 and SP3 may have a shorter resonance distance than the second sub-pixel SP2 due to the first and second buffer patterns BFP1′ and BFP2′. For example, the resonance distance of each sub-pixel may be adjusted so that light in the wavelength range of the corresponding color is effectively and efficiently amplified.

As depicted in FIG. 14, the first and second buffer patterns BFP1′ and BFP2′ are shown to be respectively disposed below the first and third anode electrodes AE1′ and AE3′, but embodiments are not limited thereto. For example, one of the first and second buffer patterns BFP1′ and BFP2′ may be omitted. As another example, both the first and second buffer patterns BFP1′ and BFP2′ may be omitted. For example, the resonance distances between respective anode electrodes and the cathode electrode CE may be the same. As another example, a buffer pattern may be disposed below each of the first to third anode electrodes AE1′ to AE3′. For example, the buffer patterns disposed below respective anode electrodes may have different thicknesses, and accordingly, the resonance distances between respective anode electrodes and the cathode electrode CE may be different from each other. As described above, by providing the buffer pattern for adjusting the height of the anode electrode below at least one of the first to third anode electrodes AE1′ to AE3′, the resonance distance in each sub-pixel may be optimized.

The pixel defining layer PDL′ may be disposed on portions of the first to third anode electrodes AE1′ to AE3′ and on the via layer VIAL. The pixel defining layer PDL′ has an opening OP′ exposing a portion of each of the first to third anode electrodes AE1′ to AE3′. An area overlapping the pixel defining layer PDL′ may be understood as the boundary area BDA between adjacent sub-pixels.

The pixel defining layer PDL′ may include multiple inorganic insulating layers sequentially stacked. Each of multiple inorganic insulating layers may include at least one of a silicon oxide (SiOₓ) and a silicon nitride (SiNₓ). However, embodiments are not limited thereto. For example, the pixel defining layer PDL may include an organic insulating layer.

The pixel defining layer PDL′ may include first to fourth inorganic insulating layers ISL1′ to ISL4′. The first inorganic insulating layer ISL1′ may cover portions of the first to third anode electrodes AE1′ to AE3′ and the via layer VIAL. The second inorganic insulating layer ISL2′ may be disposed on the first inorganic insulating layer ISL1′, the third inorganic insulating layer ISL3′ may be disposed on the second inorganic insulating layer ISL2′, and the fourth inorganic insulating layer ISL4′ may be disposed on the third inorganic insulating layer ISL3′. The first and third inorganic insulating layers ISL1′ and ISL3′ may include a silicon nitride (SiNₓ), and the second and fourth inorganic insulating layers ISL2′ and ISL4′ may include a silicon oxide (SiOₓ), but embodiments are not limited thereto. The first inorganic insulating layer ISL1′ may be omitted.

The pixel defining layer PDL′ may include a separator SPR′ in the boundary area BDA between adjacent sub-pixels. The separator SPR′ may cause a discontinuous part such as a void VD′ to be formed in the light emitting structure EMS′. Due to the discontinuous portion, at least some of multiple layers included in the light emitting structure EMS' may be disconnected or bent.

The fourth inorganic insulating layer ISL4′ may have a wider width than the second and third inorganic insulating layers ISL2′ and ISL3′ in the first direction DR1. For example, side surfaces of the second to fourth inorganic insulating layers ISL2′ to ISL4′ adjacent to the opening OP′ may be provided as the separator SPR′.

Referring to FIG. 14 together with FIG. 13, the fourth inorganic insulating layer ISL4′ may include first to third portions P1 to P3. The second portion P2 may overlap (e.g., completely overlap) the second and third inorganic insulating layers ISL2′ and ISL3′ in the third direction DR3 (e.g., thickness direction). The first portion P1 protrudes from the second portion P2 in a direction opposite to the first direction DR1. The third portion P3 protrudes from the second portion P2 in the first direction DR1. As such, a width of the fourth inorganic insulating layer ISL4′ may be wider than those of the second and third inorganic insulating layers ISL2′ and ISL3′. For example, during the manufacturing process, the second and third inorganic insulating layers ISL2′ and ISL3′ may be undercut so as not to include portions overlapping the first and third portions P1 and P3. For example, each of the first and third portions P1 and P3 of the fourth inorganic insulating layer ISL4′ may have a shape of eaves on the second and third inorganic insulating layers ISL2′ and ISL3′.

In the boundary area BDA, the second and third inorganic insulating layers ISL2′ and ISL3′ may have the same width in the first direction DR1. However, embodiments are not limited thereto, and the second and third inorganic insulating layers ISL2′ and ISL3′ may have different widths. For example, the second inorganic insulating layer ISL2′ may have a wider width than the third inorganic insulating layer ISL3′ in the first direction DR1. As another example, the third inorganic insulating layer ISL3′ may have a wider width than the second inorganic insulating layer ISL2′ in the first direction DR1.

In the second sub-pixel SP2, the first portion P1 of the fourth inorganic insulating layer ISL4′ and the first side surface SSF1 of the second and third inorganic insulating layers ISL2′ and ISL3′ may be provided as one separator SPR′. Accordingly, the first void VD1′ adjacent to the first portion P1 of the fourth inorganic insulating layer ISL4′ may be formed in the light emitting structure EMS′. In the third sub-pixel SP3, the third portion P3 of the fourth inorganic insulating layer ISL4′ and the second side surface SSF2 of the second and third inorganic insulating layers ISL2′ and ISL3′ may be provided as another separator SPR′. Accordingly, the second void VD2′ adjacent to the third portion P3 of the fourth inorganic insulating layer ISL4′ may be formed in the light emitting structure EMS′.

Some of multiple layers stacked in the light emitting structure EMS' may be disconnected or bent by the first and second voids VD1′ and VD2′. For example, at least one charge generation layer and at least one hole injection layer included in the light emitting structure EMS may be disconnected by the first and second voids VD1′ and VD2′. As described above, due to the separator SPR′, the portions of the light emitting structure EMS' included in the first to third sub-pixels SP1 to SP3 may be at least partially separated from each other.

The pixel defining layer PDL′ may include an additional separator so that the light emitting structure EMS' further may include a discontinuous portion in the boundary area BDA. The pixel defining layer PDL′ may include one or more trenches as a separator in the boundary area BDA. The trenches may penetrate one or more of the first to fourth inorganic insulating layers ISL1′ to ISL4′. Due to the trenches, some of multiple layers stacked in the light emitting structure EMS′, for example, at least one charge generation layer and at least one hole injection layer, may be disconnected or bent. The light emitting structure EMS' may have a structure in which three light emitting portions each including a light emitting layer are stacked, and two charge generation layers may be disposed between the three light emitting portions. The pixel defining layer PDL′ may include one or more trenches in the boundary area BDA.

Referring again to FIG. 13, the light emitting structure EMS' may be disposed on the anode electrodes AE exposed by the opening OP′ of the pixel defining layer PDL′. The light emitting structure EMS' may fill the opening OP′ of the pixel defining layer PDL′, and may be disposed across (e.g., entirely across) the first to third sub-pixels SP1 to SP3. As described above, the light emitting structure EMS' may be disconnected or bent in the boundary area BDA or an area adjacent to the boundary area BDA by the separator SPR′. Accordingly, during the operation of the display panel DP, the current flowing out from each of the first to third sub-pixels SP1 to SP3 through the layers included in the light emitting structure EMS' may decrease. Accordingly, the first to third light emitting elements LD1′ to LD3′ may operate with relatively high reliability.

The light emitting structure EMS' may include two light emitting portions sequentially stacked, and each of the light emitting portions may include a light emitting layer that generates light according to an applied current. In other embodiments, the light emitting structure EMS' may include three light emitting portions sequentially stacked, and each of the light emitting portions may include a light emitting layer to generate light according to an applied current. A charge generation layer may be disposed between the light emitting portions.

The light emitting structure EMS' may be formed through processes such as vacuum deposition or inkjet printing.

The cathode electrode CE may be disposed on the light emitting structure EMS′. The cathode electrode CE may be provided commonly for the first to third sub-pixels SP1 to SP3.

The first anode electrode AE1′, the portion of the light emitting structure EMS' overlapping the first anode electrode AE1′ in the third direction DR3 (e.g., thickness direction), and the portion of the cathode electrode CE overlapping the first anode electrode AE1′ may configure the first light emitting element LD1′ in the third direction DR3 (e.g., thickness direction). The second anode electrode AE2′, the portion of the light emitting structure EMS' overlapping the second anode electrode AE2′ in the third direction DR3 (e.g., thickness direction), and the portion of the cathode electrode CE overlapping the second anode electrode AE2′ may configure the second light emitting element LD2′ in the third direction DR3 (e.g., thickness direction). The third anode electrode AE3′, the portion of the light emitting structure EMS' overlapping the third anode electrode AE3′ in the third direction DR3 (e.g., thickness direction), and the portion of the cathode electrode CE overlapping the third anode electrode AE3′ may configure the third light emitting element LD3′ in the third direction DR3 (e.g., thickness direction).

The encapsulation layer TFE may be disposed on the cathode electrode CE. The encapsulation layer TFE may prevent oxygen and/or moisture from penetrating into the light emitting element layer LDL′.

An optical functional layer OFL, an overcoat layer OC, and a cover window CW may be disposed on the encapsulation layer TFE. The optical functional layer OFL, the overcoat layer OC, and the cover window CW may be similarly configured to the optical functional layer OFL, the overcoat layer OC, and the cover window CW of FIG. 7 and the like, respectively. Duplicate descriptions of these are omitted.

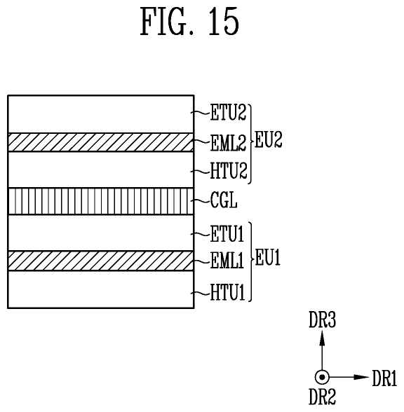

FIG. 15 illustrates a schematic cross-sectional view of a portion of a light emitting structure included in one of first to third light emitting elements of FIG. 7 to FIG. 11 or FIG. 13 according to an embodiment.

Referring to FIG. 15, the light emitting structure may have a tandem structure in which first and second light emitting portions EU1 and EU2 may be stacked in the third direction DR3 (e.g., thickness direction). The light emitting structure may be substantially the same in each of the first to third light emitting elements LD1 to LD3 of FIG. 7 and the like.

Each of the first and second light emitting portions EU1 and EU2 may include at least one light emitting layer that generates light according to a current applied thereto. The first light emitting portion EU1 may include a first light emitting layer EML1, a first electron transport portion ETU1, and a first hole transport portion HTU1. The first light emitting layer EML1 may be disposed between the first electron transport portion ETU1 and the first hole transport portion HTU1. The second light emitting portion EU2 may include a second light emitting layer EML2, a second electron transport portion ETU2, and a second hole transport portion HTU2. The second light emitting layer EML2 may be disposed between the second electron transport portion ETU2 and the second hole transport portion HTU2.

Each of the first and second hole transport portions HTU1 and HTU2 may include at least one of a hole injection layer and a hole transport layer, and may further include a hole buffer layer, an electron blocking layer, or the like as needed. The first and second hole transport portions HTU1 and HTU2 may have the same configuration or different configurations.

Each of the first and second electron transport portions ETU1 and ETU2 may include at least one of an electron injection layer and an electron transport layer, and may further include an electron buffer layer and a hole blocking layer as needed. The first and second electron transport portions ETU1 and ETU2 may have the same configuration or different configurations.

A connection layer, which may be provided in the form of a charge generation layer CGL, may be disposed between the first light emitting portion EU1 and the second light emitting portion EU2 to electrically connect them to each other. The charge generation layer CGL may have a stacked structure of a p dopant layer and an n dopant layer. For example, the p dopant layer may include a p-type dopant such as HAT-CN, TCNQ, and NDP-9, and the n dopant layer may include an alkali metal, an alkaline earth metal, a lanthanide-based metal, or a combination thereof. However, embodiments are not limited thereto.

The first light emitting layer EML1 and the second light emitting layer EML2 may generate light of different colors. The light emitted from each of the first light emitting layer EML1 and the second light emitting layer EML2 may be mixed to be recognized as white light. For example, the first light emitting layer EML1 may generate blue-colored light, and the second light emitting layer EML2 may generate yellow-colored light. The second light emitting layer EML2 may include a structure in which a first sub-light emitting layer that generates red-colored light and a second sub-light emitting layer that generates green-colored light may be stacked. The red-colored light and the green-colored light may be mixed to provide yellow-colored light. For example, an intermediate layer that performs a function of transporting holes and/or preventing transport of electrons may be further disposed between the first and second sub-light emitting layers.

In other embodiments, the first light emitting layer EML1 and the second light emitting layer EML2 may generate light of the same color.

The light emitting structure may be formed through a vacuum deposition method, an inkjet printing method, or the like, but embodiments are not limited thereto.

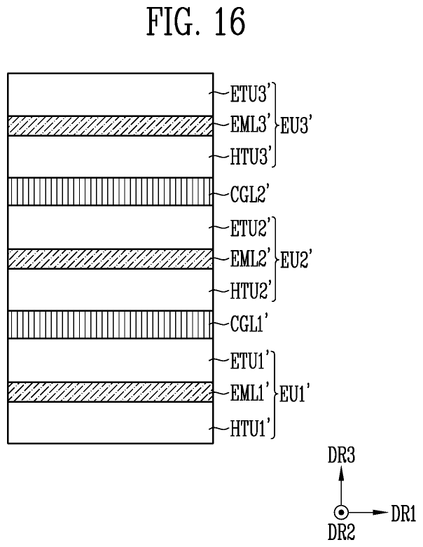

FIG. 16 illustrates a schematic cross-sectional view of a portion of a light emitting structure included in one of first to third light emitting elements of FIG. 7 to FIG. 11 or FIG. 13 according to another embodiment.

Referring to FIG. 16, the light emitting structure may have a tandem structure in which first to third light emitting portions EU1′ to EU3′ may be stacked in the third direction DR3 (e.g., thickness direction). The light emitting structure may be substantially the same in each of the first to third light emitting elements LD1 to LD3 of FIG. 7 and the like.

Each of the first to third light emitting portions EU1′ to EU3′ may include a light emitting layer that generates light according to a current applied thereto. The first light emitting portion EU1′ may include a first light emitting layer EML1′, a first electron transport portion ETU1′, and a first hole transport portion HTU1′. The first light emitting layer EML1′ may be disposed between the first electron transport portion ETU1′ and the first hole transport portion HTU1′. The second light emitting portion EU2′ may include a second light emitting layer EML2′, a second electron transport portion ETU2′, and a second hole transport portion HTU2′. The second light emitting layer EML2′ may be disposed between the second electron transport portion ETU2′ and the second hole transport portion HTU2′. The third light emitting portion EU3′ may include a third light emitting layer EML3′, a third electron transport portion ETU3′, and a third hole transport portion HTU3′. The third light emitting layer EML3′ may be disposed between the third electron transport portion ETU3′ and the third hole transport portion HTU3′.

Each of the first to third hole transport portions HTU1′ to HTU3′ may include at least one of a hole injection layer and a hole transport layer, and may further include a hole buffer layer, an electron blocking layer, or the like as needed. The first to third hole transport portions HTU1′ to HTU3′ may have the same configuration or different configurations.

Each of the first to third electron transport portions ETU1′ to ETU3′ may include at least one of an electron injection layer and an electron transport layer, and may further include an electron buffer layer and a hole blocking layer as needed. The first to third electron transport portions ETU1′ to ETU3′ may have the same configuration or different configurations.

A first charge generation layer CGL1′ may be disposed between the first light emitting portion EU1′ and the second light emitting portion EU2′. A second charge generation layer CGL2′ may be disposed between the second light emitting portion EU2′ and the third light emitting portion EU3′.

The first to third light emitting layers EML1′ to EML3′ may generate light of different colors. Light emitted from each of the first to third light emitting layers EML1′ to EML3′ may be mixed to be viewed as white light. For example, the first light emitting layer EML1′ may generate light of a blue color, the second light emitting layer EML2′ may generate light of a green color, and the third light emitting layer EML3′ may generate light of a red color.

In other embodiments, two or more of the first to third light emitting layers EML1′ to EML3′ may generate light of the same color.

Unlike as illustrated in FIG. 15 and FIG. 16, the light emitting structure may include one light emitting portion in each of the first to third light emitting elements LD1 to LD3. For example, the light emitting portions respectively included in the first to third light emitting elements LD1 to LD3 may emit light of different colors. For example, the light emitting portion of the first light emitting element LD1 may emit red-colored light, the light emitting portion of the second light emitting element LD2 may emit green-colored light, and the light emitting portion of the third light emitting element LD3 may emit blue-colored light. For example, the light emitting portions of the first to third sub-pixels SP1 to SP3 may be separated from each other, and each of them may be disposed in the opening (see OP in FIG. 7 and the like and OP′ in FIG. 13) of the pixel defining layer (see PDL in FIG. 7 and the like and PDL′ in FIG. 13)

For example, at least some of the color filters CF1 to CF3 may be omitted.

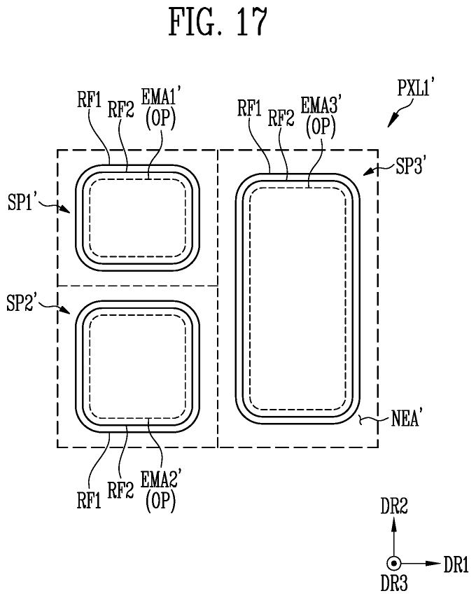

FIG. 17 illustrates a schematic top plan view of one of pixels of FIG. 5 according to another embodiment.

Referring to FIG. 17, a first pixel PXL1′ may include first to third sub-pixels SP1′ to SP3′.

The first sub-pixel SP1′ may include a first light emitting area EMA1′ and a non-light emitting area NEA′ around the first light emitting area EMA1′. The second sub-pixel SP2′ may include a second light emitting area EMA2′ and a non-light emitting area NEA′ around the second light emitting area EMA2′. The third sub-pixel SP3′ may include a third light emitting area EMA3′ and a non-light emitting area NEA′ around the third light emitting area EMA3′.

The first sub-pixel SP1′ and the second sub-pixel SP2′ may be disposed in the second direction DR2. The third sub-pixel SP3′ may be disposed in the first direction DR1 with respect to each of the first and second sub-pixels SP1′ and SP2′. For example, the third sub-pixel SP3′ may be disposed parallel to the first sub-pixel SP1′ and the second sub-pixel SP2′ in the first direction DR1.

The second sub-pixel SP2′ may have a larger area than the first sub-pixel SP1′ in a plan view, and the third sub-pixel SP3′ may have a larger area than the second sub-pixel SP2′ in a plan view. Accordingly, the second light emitting area EMA2′ may have a larger area than the first light emitting area EMA1′, and the third light emitting area EMA3′ may have a larger area than the second light emitting area EMA2′ in a plan view. However, embodiments are not limited thereto. For example, the first and second sub-pixels SP1′ and SP2′ may have substantially the same area, and the third sub-pixel SP3′ may have a larger area than each of the first and second sub-pixels SP1′ and SP2′. As such, the areas of the first to third sub-pixels SP1′ to SP3′ may be variously changed depending on embodiments.

The planar shapes of the reflective layers RF1 and RF2 may follow the planar shapes of the first to third light emitting areas EMA1′ to EMA3′. For example, the planar shapes of the reflective layers RF1 and RF2 may be similar to the planar shapes of the first to third light emitting areas EMA1′ to EMA3′, respectively.

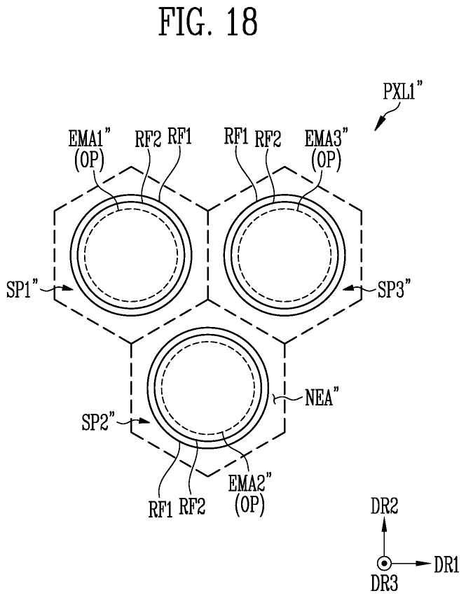

FIG. 18 illustrates a schematic top plan view of one of pixels of FIG. 5 according to another embodiment.

Referring to FIG. 18, the first sub-pixel SP1″ may include a first light emitting area EMA1″ and a non-light emitting area NEA″ around the first light emitting area EMA1″. The second sub-pixel SP2″ may include a second light emitting area EMA2″ and a non-light emitting area NEA″ around the second light emitting area EMA2″. The third sub-pixel SP3″ may include a third light emitting area EMA3″ and a non-light emitting area NEA″ around the third light emitting area EMA3″.

The first to third sub-pixels SP1″ to SP3″ may have polygonal shapes in case that viewed in the third direction DR3 (or in a plan view). For example, the shapes of the first to third sub-pixels SP1″ to SP3″ may have hexagonal shapes as shown in FIG. 18.

The first to third light emitting areas EMA1″ to EMA3″ may have circular shapes in case that viewed in the third direction DR3 (or in a plan view). However, embodiments are not limited thereto. For example, each of the first to third light emitting areas EMA1″ to EMA3″ may have a polygonal shape.

The first and third sub-pixels SP1″ and SP3″ may be disposed in the first direction DR1. The second sub-pixel SP2″ may be disposed in a direction (or a diagonal direction) inclined by an acute angle with respect to the second direction DR2 with respect to the first sub-pixel SP1″.

The planar shapes of the reflective layers RF1 and RF2 may follow the planar shapes of the first to third light emitting areas EMA1″ to EMA3″. For example, the planar shapes of the reflective layers RF1 and RF2 may be similar to the planar shapes of the first to third light emitting areas EMA1″ to EMA3″, respectively.

The positions of the sub-pixels illustrated in FIG. 6, FIG. 17, and FIG. 18 are merely examples, and embodiments are not limited thereto.

Each pixel may include two or more sub-pixels, the sub-pixels may be variously disposed, each of the sub-pixels may have various shapes, and each of its light emitting areas may also have various shapes.

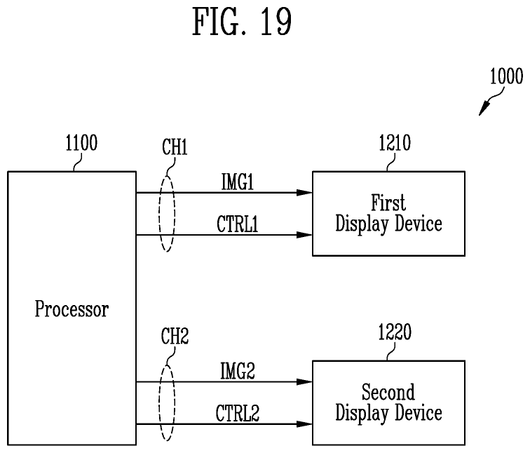

FIG. 19 illustrates a schematic block diagram of a display system according to an embodiment.

Referring to FIG. 19, the display system 1000 may include a processor 1100 and one or more display devices 1210 and 1220.

The processor 1100 may perform various tasks and calculations. The processor 1100 may include an application processor, a graphics processor, a microprocessor, a central processing unit (CPU), and the like. The processor 1100 may be electrically connected to and step other constituent elements of the display system 1000 through a bus system.

As depicted in FIG. 19, the display system 1000 is shown to include the first and second display devices 1210 and 1220. The processor 1100 may be electrically connected to the first display device 1210 through a first channel CH1 and to the second display device 1220 through a second channel CH2.

Through the first channel CH1, the processor 1100 may transmit first image input IMG1 and a first control signal CTRL1 to the first display device 1210. The first display device 1210 may display an image based on the first image input IMG1 and the first control signal CTRL1. The first display device 1210 may be similarly configured to the display device 100 described with reference to FIG. 1. For example, the first image input IMG1 and the first control signal CTRL1 may be provided as the input image input IMG and the control signal CTRL of FIG. 1, respectively.

Through the second channel CH2, the processor 1100 may transmit second image input IMG2 and a second control signal CTRL2 to the second display device 1220. The second display device 1220 may display an image based on the second image input IMG2 and the second control signal CTRL2. The second display device 1220 may be similarly configured to the display device 100 described with reference to FIG. 1. For example, the second image input IMG2 and the second control signal CTRL2 may be provided as the input image input IMG and the control signal CTRL of FIG. 1, respectively.

The display system 1000 may include a computing system providing image display functions such as a portable computer, a mobile phone, a smart phone, a tablet personal computer (PC), a smart watch, a watch phone, a portable multimedia player (PMP), a navigation system and an ultra mobile personal computer (UMPC). The display system 1000 may include at least one of a head-mounted display device (HMD), a virtual reality (VR) device, a mixed reality (MR) device, and an augmented reality (AR) device.

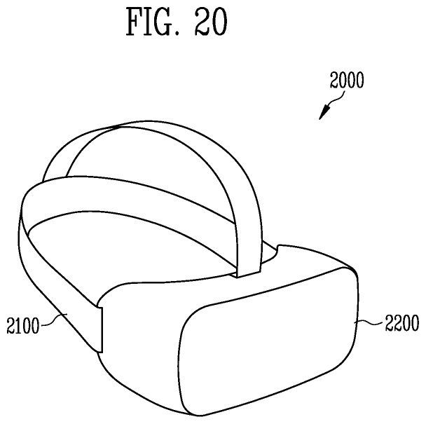

FIG. 20 illustrates a schematic perspective view of an application example of the display system of FIG. 19.

Referring to FIG. 20, the display system 1000 of FIG. 19 may be applied to a head-mounted display device 2000. The head-mounted display device 2000 may be a wearable electronic device that is worn on the user's head.

The head-mounted display device 2000 may include a head-mounted band 2100 and a display device accommodation case 2200. The head-mounted band 2100 may be connected to the display device accommodation case 2200. The head-mounted band 2100 may include a horizontal band and/or a vertical band for fixing the head-mounted display device 2000 to the user's head. The horizontal band may surround the side portion of the user's head, and the vertical band may surround the upper portion of the user's head. However, embodiments are not limited thereto. For example, the head-mounted band 2100 may be implemented in the form of a spectacle frame, a helmet, or the like.

The display device accommodation case 2200 may accommodate the first and second display devices 1210 and 1220 of FIG. 19. The display device accommodation case 2200 may further accommodate the processor 1100 of FIG. 19.

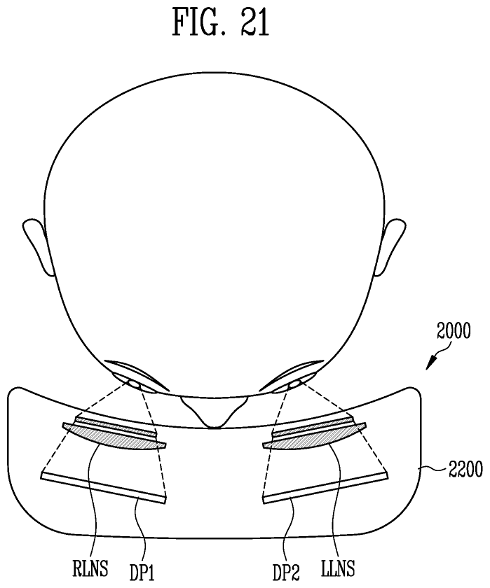

FIG. 21 illustrates a schematic head-mounted display device of FIG. 20 worn by a user.

Referring to FIG. 21, a first display panel DP1 of the first display device 1210 and a second display panel DP2 of the second display device 1220 may be disposed in the head mounted display device 2000. The head-mounted display device 2000 may further include one or more lenses LLNS and RLNS.

In the display device accommodation case 2200, the right eye lens RLNS may be disposed between the first display panel DP1 and the right eye of the user. In the display device accommodation case 2200, the left eye lens LLNS may be disposed between the second display panel DP2 and the left eye of the user.

An image output from the first display panel DP1 may be shown to the right eye of the user through the right eye lens RLNS. The right eye lens RLNS may refract light from the first display panel DP1 to be directed to the right eye of the user. The right eye lens RLNS may perform an optical function to adjust the viewing distance between the first display panel DP1 and the right eye of the user.

An image output from the second display panel DP2 may be shown to the left of the user through the left eye lens LLNS. The left eye lens LLNS may refract light from the second display panel DP2 to be directed to the left eye of the user. The left eye lens LLNS may perform an optical function to adjust the viewing distance between the second display panel DP2 and the left eye of the user.

Each of the right eye lens RLNS and the left eye lens LLNS may include an optical lens having a cross-section of a pancake shape. Each of the right eye lens RLNS and the left eye lens LLNS may include a multi-channel lens including sub-areas with different optical characteristics. For example, each display panel outputs images corresponding to the sub-areas of the multi-channel lens, and the output images may pass through the sub-areas and be viewed by the user.

In other embodiments, the display system 1000 shown in FIG. 19 may be applied to, a smart watch, a mobile phone, a smartphone, a portable computer, a tablet personal computer (PC), a watch phone, an automotive display, a smart glass, a portable multimedia player (PMP), a navigation system, an ultra-mobile computer (UMPC), a virtual reality (VR) device, a mixed reality (MR) device, and an augmented reality (AR) device.

Subsequently, a manufacturing method of the display device according to the above-described embodiment will be described.

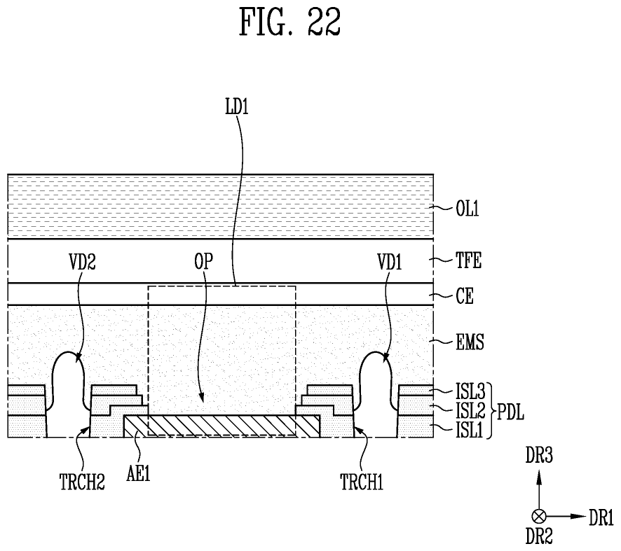

FIG. 22 to FIG. 28 illustrate schematic cross-sectional views of process steps of a manufacturing method of a display device according to an embodiment. For better understanding and ease of description, the illustrations are simplified and redundant explanations are omitted.

Referring to FIG. 22, the first organic layer OL1 may be formed on the encapsulation layer TFE. The first anode electrode AE1, the light emitting structure EMS, and/or the cathode electrode CE, including the encapsulation layer TFE, have been described in detail with reference to FIG. 1 to FIG. 21, so redundant descriptions will be omitted.

The first organic layer OL1 may be formed using an acrylic resin, an epoxy resin, a phenol resin, a polyamide resin, a polyimide resin, an unsaturated polyester resin, a polyphenyleneether resin, a polyphenylenesulfide resin, or benzocyclobutene (BCB), but is not necessarily limited thereto.

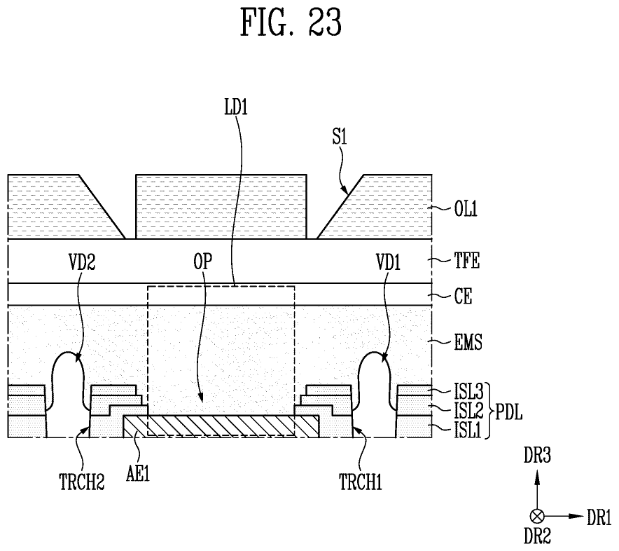

Referring to FIG. 23, the first organic layer OL1 may be etched to form the first inclined surface S1. The first inclined surface S1 may overlap the pixel defining layer PDL in the third direction DR3 (e.g., thickness direction). The first inclined surface S1 may not overlap the opening OP of the pixel defining layer PDL in the third direction DR3 (e.g., thickness direction), but is not limited thereto.

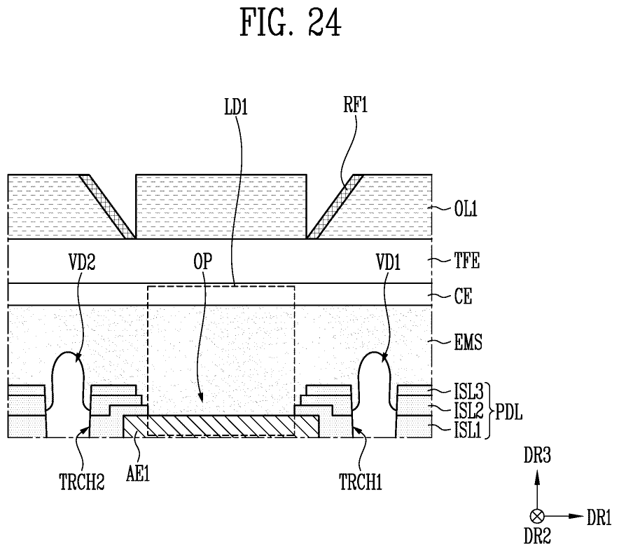

Referring to FIG. 24, next, the first reflective layer RF1 may be formed on the first organic layer OL1. The first reflective layer RF1 may be formed (e.g., directly formed) on the first organic layer OL1. The first reflective layer RF1 may be formed on the first inclined surface S1.

The first reflective layer RF1 may be formed of a metallic material. For example, the first reflective layer RF1 may be formed of at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti) and an alloy of two or more materials selected therefrom, but embodiments are not limited thereto. In some embodiments, the first reflective layer RF1 may be formed to have a structure in which inorganic films may be alternately stacked in the third direction DR3 (e.g., thickness direction). For example, the first reflective layer RF1 may be formed to have a structure in which a silicon oxide (SiOₓ) and a titanium oxide (TiOₓ) may be alternately stacked in the third direction DR3 (e.g., thickness direction).

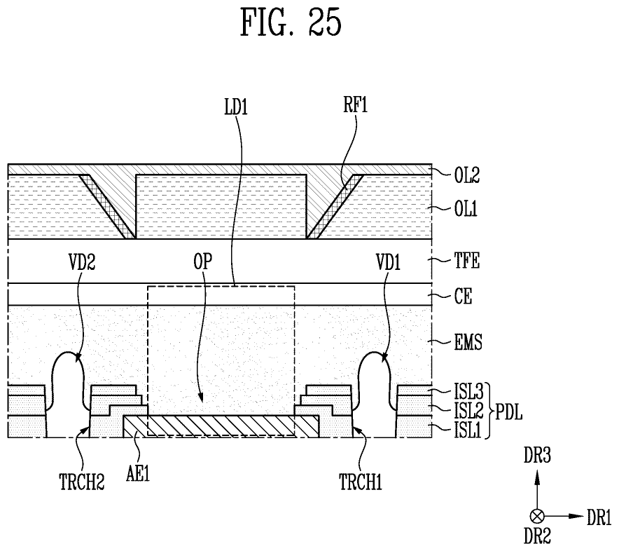

Referring to FIG. 25, the second organic layer OL2 may be then formed on the first organic layer OL1 and/or the first reflective layer RF1. The second organic layer OL2 may be formed using an acrylic resin, an epoxy resin, a phenol resin, a polyamide resin, a polyimide resin, an unsaturated polyester resin, a polyphenyleneether resin, a polyphenylenesulfide resin, or benzocyclobutene (BCB), but is not necessarily limited thereto. The second organic layer OL2 may be formed of the same material as the first organic layer OL1, but is not limited thereto.

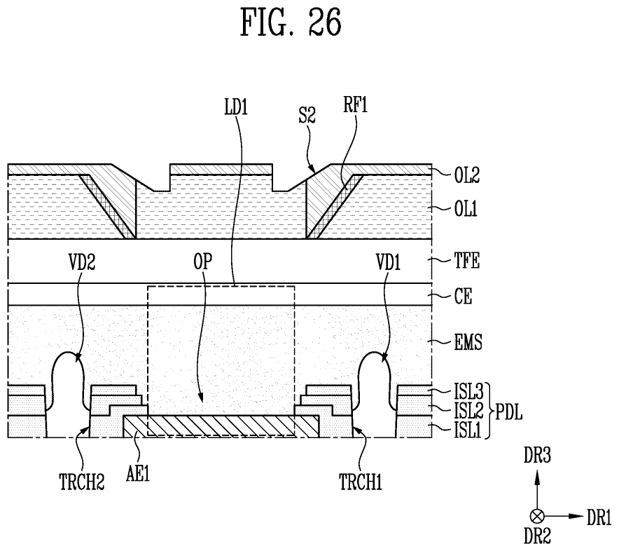

Referring to FIG. 26, the second organic layer OL2 may be then etched to form the second inclined surface S2. In some embodiments, the first organic layer OL1 may be partially etched in the process of forming the second inclined surface S2. The inclination angle of the second inclined surface S2 may be different from the inclination angle of the first inclined surface S1. For example, the inclination angle of each of the inclined surfaces S1 and S2 may mean an angle that each of the inclined surfaces S1 and S2 forms with the substrate SUB. The inclination angle of the first inclined surface S1 and/or the inclination angle of the second inclined surface S2 may be variously changed in consideration of the light emission path of light emitted from the light emitting structure EMS.

The second inclined surface S2 may overlap the opening OP of the pixel defining layer PDL in the third direction DR3 (e.g., thickness direction). The second inclined surface S2 may partially overlap the pixel defining layer PDL in the third direction DR3 (e.g., thickness direction), but is not limited thereto.

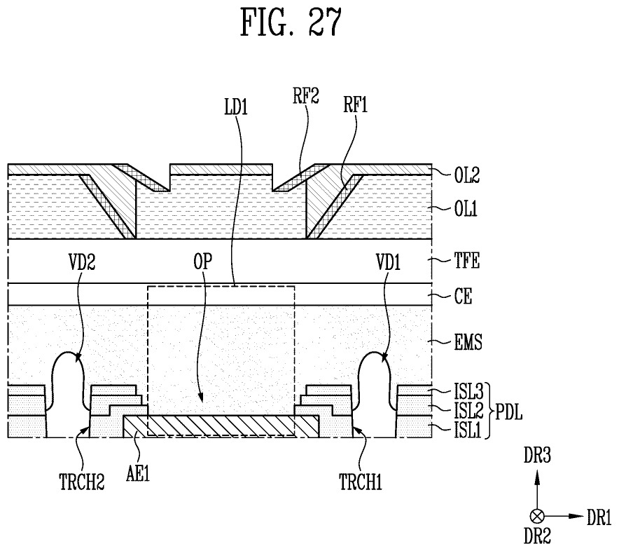

Referring to FIG. 27, the second reflective layer RF2 may be formed on the second organic layer OL2. The second reflective layer RF2 may be formed (e.g., directly formed) on the second organic layer OL2. The second reflective layer RF2 may be formed on the second inclined surface S2.

The second reflective layer RF2 may be made of a metal material. For example, the second reflective layer RF2 may be made of at least one of various transparent conductive materials including an indium tin oxide, an indium zinc oxide, an indium tin zinc oxide, an aluminum zinc oxide, a gallium zinc oxide, a zinc tin oxide, and a gallium tin oxide. In other embodiments, the second reflective layer RF2 may be formed of at least one of silver (Ag), magnesium (Mg) and a mixture thereof.

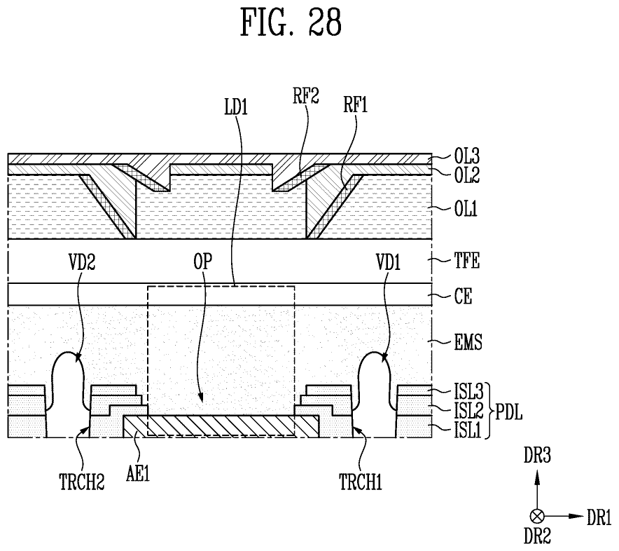

Referring to FIG. 28, the third organic layer OL3 may be formed on the second organic layer OL2 and/or the second reflective layer RF2. The third organic layer OL3 may be formed using an acrylic resin, an epoxy resin, a phenol resin, a polyamide resin, a polyimide resin, an unsaturated polyester resin, a polyphenyleneether resin, a polyphenylenesulfide resin, or benzocyclobutene (BCB), but is not necessarily limited thereto. The third organic layer OL3 may be made of the same material as the first organic layer OL1 and/or the second organic layer OL2, but is not limited thereto.

Subsequently, the passivation layer PSV may be formed on the third organic layer OL3 to form the optical layer OPL of FIG. 12. The above-described display device may be completed by forming the color filter layer CFL, the overcoat layer OC, and/or the cover window CW on the optical layer OPL.

In case that forming a micro lens of an optical layer using injection or etching, defects such as the micro lens not being accurately aligned or the shape of the micro lens being deformed may occur. Accordingly, in case that forming the optical layer OPL using the organic layer OL and the reflective layers RF1 and RF2 according to the above-described method, the process may be simplified, defects caused by the micro lens may be improved, and the light output efficiency of the display device may be improved.

Although certain embodiments and implementations have been described herein, other embodiments and modifications will be apparent from this description. Accordingly, the inventive concept is not limited to the embodiments, but rather to the broader scope of the presented claims and various obvious modifications and equivalent arrangements.

What is claimed is:

1. A display device comprising:
a first electrode;
a pixel defining layer disposed on the first electrode;
a light emitting member disposed on the first electrode and the pixel defining layer;
a second electrode disposed on the light emitting member;
an organic layer disposed on the second electrode;
a first reflective layer in the organic layer; and
a second reflective layer disposed on the first reflective layer in the organic layer,
wherein the first reflective layer overlaps the pixel defining layer, and the second reflective layer overlaps the light emitting member in a thickness direction.

2. The display device of claim 1, wherein
a planar area of the first reflective layer is larger than a planar area of the second reflective layer.

3. The display device of claim 1, wherein
the pixel defining layer includes an opening overlapping the first electrode in the thickness direction, and
the second reflective layer overlaps the opening in the thickness direction.

4. The display device of claim 1, wherein
the first reflective layer includes a first opening.

5. The display device of claim 4, wherein
the second reflective layer includes a second opening.

6. The display device of claim 5, wherein
a planar area of the first opening is larger than a planar area of the second opening.

7. The display device of claim 1, wherein
the first reflective layer and the second reflective layer includes an inclined surface.

8. The display device of claim 1, wherein
the first reflective layer and the second reflective layer includes a spherical surface.

9. The display device of claim 1, wherein
the pixel defining layer includes a separator, and
the light emitting member is at least partially separated by the separator.

10. A display device comprising:
a first electrode;
a pixel defining layer disposed on the first electrode;
a light emitting member disposed on the first electrode and the pixel defining layer;
a second electrode disposed on the light emitting member;
a first organic layer disposed on the second electrode;
a first reflective layer disposed on the first organic layer;
a second organic layer disposed on the first reflective layer; and
a second reflective layer disposed on the second organic layer,
wherein the first reflective layer overlaps the pixel defining layer, and the second reflective layer overlaps the light emitting member in a thickness direction.

11. The display device of claim 10, wherein
the first organic layer includes a first inclined surface, and
the first reflective layer is disposed on the first inclined surface.

12. The display device of claim 10, wherein
the second organic layer includes a second inclined surface, and
the second reflective layer is disposed on the second inclined surface.

13. The display device of claim 10, wherein
the first reflective layer includes a first opening.

14. The display device of claim 13, wherein
the first organic layer is disposed in the first opening.

15. The display device of claim 10, wherein
the second reflective layer includes a second opening.

16. The display device of claim 15, wherein
the second organic layer is disposed in the second opening.

17. The display device of claim 10, wherein
a planar area of the first reflective layer is larger than a planar area of the second reflective layer.

18. The display device of claim 10, further comprising:
a third organic layer on the second reflective layer.

19. The display device of claim 18, wherein
the first organic layer, the second organic layer, and/or the third organic layer include a same material.

20. An electronic device comprising:
a display device including a light emitting element disposed on a substrate,
wherein the light emitting element includes:
a first electrode;
a pixel defining layer disposed on the first electrode;
a light emitting member disposed on the first electrode and the pixel defining layer;
a second electrode disposed on the light emitting member;
an organic layer disposed on the second electrode;
a first reflective layer in the organic layer; and
a second reflective layer disposed on the first reflective layer in the organic layer,
the first reflective layer overlaps the pixel defining layer, and
the second reflective layer overlaps the light emitting member in a thickness direction.
